(19) United States
(12) Patent Application Publication
(10) Pub. No.: US 2009/0252891 A1
(43) Pub. Date: Oct. 8, 2009

(54) Structure matter of thin film particles having carbon skeleton, processes for the production of the structure matter and the thin-film particles and uses thereof

(76) Inventors: Masukazu Hirata, Ibaragi-ken (JP); Takuya Gotou, Ibaragi-ken (JP); Shigeo Horiuchi, Ibaragi-ken (JP)

Correspondence Address: WENDEROTH, LIND & PONACK, L.L.P., 1030 15th Street, N.W.,, Suite 400 East, Washington, DC, 20005-1503, US

(21) Appl. No.: 12/457,325

(22) Filed: Jun. 8, 2009

Related U.S. Application Data
(62) Division of application No. 11/540,517, filed on Oct. 2, 2006.
Application No. 11/540,517 is a division of application No. 10/359,684, filed on Feb. 7, 2003, now abandoned.

(30) Foreign Application Priority Data
Feb. 8, 2002 (JP) 2002-032881
Aug. 30, 2002 (JP) 2002-254002
Aug. 30, 2002 (JP) 2002-254030

(51) Int. Cl. B05D 3/06; C01B 31/04; G03C 1/725

(52) U.S. Cl. 427/553; 423/448; 252/600

(57) ABSTRACT

The present invention provides a structure matter composed of (a) oxidized form thin film particle(s) which are obtained by oxidizing graphite, have a thickness of 0.4 nm to 10 μm and a planar-direction size at least twice as large as the thickness, have lyophilic to a liquid having a relative dielectric constant of 15 or more and have a carbon skeleton or an oxidized form lamination layer aggregate in which the oxidized form thin film particles are combined with each other, or (b) reduced form thin film particle(s) or a reduced form lamination layer aggregate obtained by partially or completely reducing the above oxidized form thin film particle (s) or the above oxidized form lamination layer aggregate so as to have an oxygen content of 0 to 35 wt %, and (c) a substrate, the oxidized form thin film particle(s), the oxidized form lamination layer aggregate, the reduced form thin film particle(s) or the reduced form lamination layer aggregate being in contact with the substrate, its use and a method for reducing thin film particles having a carbon skeleton.

### FIELD OF THE INVENTION

The present invention relates to a structure matter in which thin film particle(s) having a carbon skeleton are mounted on a substrate, processes for the production of the structure matter and the thin film particle(s), and uses of these. More specifically, it relates to a structure matter or thin film particles that can easily utilize the electronic nature or stability peculiar to a carbonaceous material having a periodic structure and production processes of these. The present invention can be applied to fine circuits (device or wiring), circuits for high temperatures (device or wiring), opto-electric conversion devices (solar cell, light-emitting device, etc.), semiconductor devices, exothermic matters, optical devices, stable recording materials and the like.

### PRIOR ARTS

In recent years, searches for materials having high anisotropy of shape and applications thereof are proceeding rapidly. As an anisotropic shape material having carbon atoms as a skeleton, there are known one-dimensional materials such as a graphite fiber or a carbon nanotube being an especially slender graphite fiber and two-dimensional materials such as graphite, graphite fluoride and graphite oxide. Of these, each of graphite, graphite fluoride and graphite oxide is a multi-layer structure matter in which two-dimensional fundamental layers are laminated, and multi-layer structure matters having so many layers are generally known. Concerning graphite oxide, very thin graphite oxide having a small number of layers has been made (for example, N. A. Kotov et al., Adv. Mater., 8, 637 (1996)). The present inventors also have found a process for producing thin film particles of such graphite oxide (when the number of layers is one, e.g., it is preferred to call it “graphene oxide” (“graphene” is the name for one graphite layer)) in high yield and produced thin film particles having a very small number of layers similar to graphite by reducing the above thin film particles (JP-A-2002-53313). Further, the present inventors have produced especially largely outspread thin film particles, a lamination layer aggregate in which the thin film particles are laminated and outspreaded, and reductants of these (Japanese Patent Application No. 2001-374537, Japanese Patent Application No. 2001-374538).

The fundamental layer of graphite oxide is thought to have a structure in which acidic hydroxyl groups, etc., are bonded to both sides of a carbon skeleton (composed of sp³ carbon and Sp² carbon, sp³ carbon is larger in amount) having a thickness equivalent to one carbon atom or two carbon atoms (for example, T. Nakajima et al., Carbon, 26, 357 (1988); M. Mermoux et al., Carbon, 29, 469 (1991)). When the thickness of the carbon skeleton is equivalent to the size of one carbon atom, and hydroxyl groups are bonded to both sides of the carbon skeleton and interlayer water is remarkably little in amount, the thickness of the fundamental layer is 0.61 nm. Further, when graphite oxide has a high oxidation degree and is dried sufficiently, the content of oxygen in the graphite oxide is approximately 40 wt %.

Thin film particles of the above graphite oxide (to be referred to as “oxidized form thin film particles” hereinafter) come to have an electronic state having many sp² bonds similar to that of graphite by partial or complete reduction, and the thin film particles are thus increased in electric conductivity. In particular, as a general behavior of graphite oxide, reduction by heating can convert even the inside of a multi-layer particle into a structure similar to that of graphite. It is known that, when heating is carried out in a state where a plurality of the particles are bonded to each other, intermolecular forces arise in an interlayer inside each multi-layer particle or between a plurality of the particles so that a macroscopic shape like a general graphite film can be provided (J. Maire et al., Carbon, 6, 555 (1968)). The oxidized form thin film particles are converted into reduced form thin film particles by similar heating (JP-A-2002-53313).

Here, when the thin film particles are completely reduced, each fundamental layer of the thin film particles becomes almost graphite's fundamental layer (graphene). When the thin film particles are multi-layer particles, the interlayer distance is almost equal to the interlayer distance of graphite. However, each multi-layer particle has a structure of a turbostratic tendency in which the mutual positional relationship of respective layers is more turbulent than that of graphite. Further, when the thin film particles are partially reduced, oxygen and the like remain in each fundamental layer and its interlayer distance becomes larger than that of graphite.

The above oxidized form and reduced form thin film particles can be called “graphite oxide nanofilm” (“graphene oxide nanofilm”, when the number of layers is one), when the fraction of oxygen is high. When the oxygen fraction is low or no oxygen is contained, the thin film particles can be called “graphite nanofilm” (“graphene nanofilm”, when the number of layers is one). Further, uniformly, these thin film particles are respectively called an oxidized form single-layer carbon nanofilm or multilayer carbon nanofilm and a reduced form single-layer carbon nanofilm or multilayer carbon nanofilm. Using the name of “carbon nanofilm” can prevent any confusion from being caused by calling the thin film particles having a turbostratic tendency “graphite”, as described above.

Carbonaceous materials having a thickness almost equivalent to that of these thin film particles can be formed on a substrate by vapor-deposition or the like, or they can be also formed by pyrolyzing an organic compound laid on a substrate (crystal growth further called “graphitization”). However, these carbonaceous materials have a structure in which small crystals gather in a broad domain, even when they have relatively high crystallinity. Further, the formation thereof requires a high temperature condition, a vacuum condition and the like.

Various applications such as electric nature are expected from the oxidized form or reduced form thin film particles (carbon nanofilm). For example, the above applications include a fine circuit (device or conductor), a circuit for high temperature (device or conductor), an opto-electric conversion devise (solar cell, light-emitting device, etc.), an exothermic matter, an optical device, a stable recording material. The circuit for high temperature is under the following circumstances.

In recent years, there are conducted researches on a device (electronic device or optical device) using a semiconductor having a wide band gap such as diamond or silicon carbide. This device is expected to work at high velocity, at a high power, at a high temperature of up to approximately 500° C., or under high radiation or to generate ultraviolet light (for example, Hiroshi Kawarada, Oyo Buturi, 67, 128 (1999). At the present stage, discrete devices are being made. It is expected that an integrated circuit will be made before long.

In a conductor part of such a device, it is thought to use metals, graphite, its analog (carbonaceous material mainly formed of sp²) or a semiconductor which is obtained by doping impurities in a high concentration. Of these, particularly, the graphite and its analog are preferred in some cases in consideration of moderate highness of electric conductivity, smallness of degradation (oxidation, etc.) due to a high temperature at the time of production (particularly when pattern formation is carried out several times) or use (particularly in the case of a long period of time) of the device and highness of an affinity with a semiconductor part. As an example thereof, there are disclosed proton irradiation (Japanese Patent No. 2834829), ion-implantation and heating (JP-A-07-37835), electron-beam or laser irradiation (JP-A-10-261712), etc., concerning a method for graphitizing part of diamond. Further, thinkable is a method graphitizing an organic compound forming a pattern on diamond. However, these methods have problems such as poor position selectivity, degradation of a semiconductor part due to a need of heating at a high temperature for a long period of time, and the like. Some methods are devised as a method for hydrophilization of such semiconductor materials having a wide band gap. As for a diamond substrate, for example, there is devised oxygen plasma irradiation or a method in which the substrate is brought into contact with a hydrogen peroxide aqueous solution and then irradiated with ultraviolet light (JP-A-10-17314, the contact angle to water is changed from 90 degree to 40 degree before and after treatment). As for silicon carbide, there is devised a method in which hydrophilization is concurrently carried out at the time of formation of a film (Japanese Patent No. 2923275).

In the above various applications, for stably utilizing the electronic nature, etc., of the thin film particles for a long period of time, it is required to mount an isolated thin film particle or a plurality of thin film particles on a substrate with high adhesion and then process the particle(s) so as to have a desired size and a desired shape. Furthermore, when an electric current is fed through the processed thin film particle(s), a connection to an outer electric circuit, etc., is required. However, concrete methods therefor have not been proposed.

The present inventors have disclosed thin film particles which are obtained by oxidizing graphite and which have a thickness of 0.4 to 10 nm and a planar direction size of 20 nm or more, are dispersible in a liquid having a relative dielectric constant of 15 or more and have a carbon skeleton in JP-A-2002-53313. In the specification thereof, the present inventors indicate that heating, a reducing agent or an electrode reaction can reduce the thin film particles. Further, the present inventors have disclosed large-sized thin film particles having a planar direction size of 500 μm or more and a carbon skeleton in Japanese Patent Application No. 2001-374537 and similarly indicated that heating, a reducing agent or an electrode reaction can reduce these thin film particles too. The above graphite oxide contains about 30 to 40 wt % of oxygen.

Although the above graphite oxide generally has a high resistivity of about 10⁶ to 10⁸ Ω·cm and has remarkably low electric conductivity, it is known that the above graphite oxide comes to have an electronic state having many sp² bonds analogous to graphite by partial or complete reduction and is thus increased in electric conductivity. The graphite oxide increased in electric conductivity by the reduction can be applied, as a semiconductor or a conductor, in various fields such as semiconductor devices, wiring materials, fillers for anti-electrification and anti-electrostatic, so that it is remarkably useful.

These thin film particles can be obtained as a dispersion thereof in a high polarity liquid. When the graphite oxide increased in electric conductivity is used as a thin film layer for a semiconductor device or wiring, preferred is a method in which after applying the above dispersion to a desired substrate, the thin film particles are reduced by heating.

On the other hand, if the above thin film layer formed of the thin film particles can be selectively reduced only in a specific part, it becomes possible to form a desired wiring pattern after forming the thin film layer on the entire surface of a substrate. However, when the reduction is carried out by heating, the whole of the thin film layer is heated so that it is difficult to selectively reduce only the specific part.

Further, when thin film particles increased in electric conductivity are added to a resin for the purpose of anti-electrification, anti-electrostatic or gas-barrier, it is important that the thin film particles are added in a high-dispersed state for utilizing characteristics of an anisotropic shape. Therefore, it is preferred to add the thin film particles to the resin while holding a high-dispersed state in a dispersion in which the thin film particles are synthesized.

However, when the above thin film particles are taken out from the dispersion and then reduced by heating, the particles adhere to each other to undergo aggregation so that the previous dispersed state can not be held. In order to add the thin film particles increased in electric conductivity to a resin while holding a high-dispersed state, the thin film particles are reduced in the dispersion and then the dispersion, as it is, is added to the resin in a molten state or a solution in which the resin is dissolved. Otherwise, there is another method in which the thin film particles are reduced in the dispersion, then the resultant dispersion is sprayed at a high temperature to dry the thin film particles instantaneously and to obtain thin film particles having no aggregation, and then the particles are added to the resin. It is important that the reduction is carried out in the dispersion.

As a method for the reduction in the dispersion, there can be adopted a method using a reducing agent. However, steps of removal of the reducing agent used and purification are complicate so that the above method is not preferable.

Semiconductor devices are widely divided into a device using an inorganic semiconductor and a device using an organic semiconductor. Both are studied for various devices such as a field effect transistor, a solar cell, an organic electroluminescence (“EL” hereinafter).

An inorganic semiconductive material has electric characteristics that an organic semiconductive material does not have, e.g., its mobility is higher than that of the organic semiconductive material. For example, the mobility of a single crystal silicon is approximately 1,500 (cm²V⁻¹s⁻¹), the mobility of a polycrystal silicon is approximately 30 to 200 (cm²V⁻¹s⁻¹) and the mobility of an amorphous silicon is approximately 0.5 to 1 (cm²V⁻¹s⁻¹).

On the other hand, the organic semiconductive material has characteristics that the inorganic semiconductor does not have. As its characteristics, the organic semiconductive material is lightweight and thin and has flexibility and it is easy to make an organic semiconductive material having a large area. These characteristics are utilized to the maximum when the organic semiconductive material is used for a device which is lightly bendable like a paper, such as an electronic paper. However, the mobility of the organic semiconductive material is low at the present stage, which prevents it from going into actual use. For example, “lightweight and soft organic transistor changes the form of a display” in Nikkei Electronics, issue 2001 Oct. 8, page 55, published by Nikkei Business Publications, Inc., describes a current trend of an organic semiconductor.

Examples of an organic semiconductive material having a large mobility include single crystals of acenes such as anthracene, tetracene and pentacene. As for these organic semiconductive materials, about 1 (cm²V⁻¹s⁻¹) is reported. Particularly, it is known that the single crystal of pentacene functions as an ambipolar (J. H. SchÖn, et al., Science Vol. 287, 1022 (2000)). A general material is monopole and it functions as either of P type (hole transport) or N type (electron transport). In contrast, an ambipolar material functions as both of P type and N type. Materials having such ambipolar properties are very rare. There have been known almost no reports other than the pentacene. Further, even in the case of the pentacene, only pentacene having a highly-increased purity exerts the above phenomenon and general pentacene shows only P type.

The ambipolar material has a great advantage when used for a CMOS circuit. Generally, the CMOS circuit contains both a P type channel domain and an N type channel domain. When monopole materials are used, it is required to carry out each patterning independently. On the other hand, when the ambipolar material is used, only one kind of material is required to work the CMOS circuit. This simplifies a manufacturing process so that a considerable cost reduction effect can be expected (concerning a CMOS device using an ambipolar type material, for example, JP-A-2001-177109 and JP-A-2002-26336 have detailed descriptions).

These single crystals of acenes have effective electric characteristics. However, it is difficult to form a film from a solution since they are not easily dissolved in an organic solvent. Therefore, an expensive vapor-deposition apparatus is necessary so that it is disadvantageous in view of a cost. Further, it is difficult to form a homogeneous film in a broad domain by vapor deposition. The vapor deposition is not suitable for forming a large-area film.

On the other hand, macromolecular materials typified by polythiophene type materials are listed as an organic semiconductive material valued in film-forming properties. It is easy to prepare a high concentration solution from the macromolecular materials as compared with a small molecular system. Accordingly, an expensive film forming apparatus is not needed which is generally used for the inorganic semiconductive material, and a low-priced technique such as spincoating, screen printing or inkjet printing can be used. So, a considerable cost reduction effect can be expected. However, the mobility is generally low. Generally-known mobility is approximately 10⁻⁶ (cm²V⁻¹s⁻¹).

An organic semiconductor is used for a hole transport layer or an electron transport layer of an organic EL device. In view of prevention of the occurrence of pinholes in a thin film state, these transport layers are required to maintain a uniform amorphous state for preventing easy crystallization. For this reason, it is required that the glass transition temperature of a material is high, preferably 200° C. or higher. Furthermore, for increasing the response speed of a device, it is important that mobility for a hole in the hole transport layer and mobility for an electron in the electron transport layer are respectively high. There are some references, e.g., “Organic EL device and forefront of industrialization”, published by N•T•S, 1988), “Trend of materials development supporting an organic EL Display” at page 17 in the 2001 December issue of “Electronic material” published by Kogyo Chosakai Publishing Co., Ltd., and “New development of organic EL” at page 6 in the 2001 August issue of “Kinou Zairyo” published by CMC Publishing Co., Ltd.

Organic materials used in the hole transport layer or the electron transport layer of the organic EL device include aromatic amines as a typical hole transport material. In particular, TPD (triphenylamine dimer) which is a dimer of triphenylamine is known as a typical hole transport material. From the above TPD, a homogeneous amorphous thin film can be easily formed on a substrate by vacuum deposition. However, TPD has a low glass transition temperature of about 60° C. When a long period of time passes, it undergoes crystallization even at room temperature and it converts to a nonuniform film. A change of a film structure in accordance with the crystallization directly affects the life of EL device. Further, compounds containing oxadiazole (PBD, BND) or a triazole structure (TAZ) are known as an electron transport material. However, most of these materials have a low glass transition temperature and are apt to undergo crystallization. Therefore, it is difficult to obtain a stable device by using these compounds as an electron transport material. Further, “New development of organic EL” at page 6 in the 2001 August issue of “Kinou Zairyo” published by CMC Publishing Co., Ltd., has a description indicating that hole transport materials and electron transport materials with high mobility are not present, which is a cause to use an ultrathin film difficult to form. This article indicates the necessity of an organic semiconductive material with high mobility.

Although the organic semiconductive material is inferior in electric performance to the inorganic semiconductive material, it has excellent advantages that the inorganic semiconductor does not have. For example, a manufacturing cost is extremely low and the organic semiconductive material is lightweight, thin and flexible. However, although various materials have been proposed as an organic semiconductor material, there has not been yet obtained an organic semiconductor material having sufficient properties. For these reasons, development of a novel type semiconductive material, unlike conventional inorganic semiconductors or conventional organic semiconductors, is expected.

### SUMMARY OF THE INVENTION

It is an object of the present invention to provide a structure matter which can stably utilize the electronic properties of thin film particles (carbon nanofilm) which are obtained by oxidizing graphite and have a carbon skeleton or a lamination layer aggregate of these for a long period of time, and a process for the production thereof.

It is another object of the present invention to provide a novel method for reducing thin film particles which are obtained by oxidizing graphite and have a carbon skeleton, a dispersion of the above thin film particles or a thin film layer formed of the above thin film particles, easily and selectively in a predetermined position.

It is further another object of the present invention to provide an organic semiconductor which utilizes excellent properties, such as lightness and bendability, that an inorganic semiconductor does not have and is excellent in electrical performance as a semiconductor.

The present invention 1 provides a structure matter composed of

(a) oxidized form thin film particle(s) which are obtained by oxidizing graphite, have a thickness of 0.4 nm to 10 μm and a planar-direction size at least twice as large as the thickness, have lyophilic to a liquid having a relative dielectric constant of 15 or more and have a carbon skeleton or an oxidized form lamination layer aggregate in which the oxidized form thin film particles are combined with each other, or

(b) reduced form thin film particle(s) or a reduced form lamination layer aggregate obtained by partially or completely reducing the above oxidized form thin film particle(s) or the above oxidized form lamination layer aggregate so as to have an oxygen content of 0 to 35 wt %, and

(c) a substrate,

the oxidized form thin film particle(s), the oxidized form lamination layer aggregate, the reduced form thin film particle(s) or the reduced form lamination layer aggregate being in contact with the substrate, its production process and its use.

The present invention 2 provides a method for reducing thin film particles which are obtained by oxidizing graphite, are dispersible in a liquid having a relative dielectric constant of 15 or higher and have a carbon skeleton, which method comprises irradiating the thin film particles with light, and a method for forming a thin film layer formed of the above thin film particles.

The present invention 3 provides a semiconductor device composed of a substrate, a semiconductor layer formed on the substrate and a junction for passing an electric current to the semiconductor layer, wherein the semiconductor layer is made of thin film particle(s) obtained by oxidizing graphite, and thin film particle(s) having high mobility used for the above semiconductor device.

### BRIEF DESCRIPTION OF DRAWINGS

FIG. 1 shows a schematic drawing showing an example in which electric properties are changed by a shape (in the case of a field effect transistor, processing is carried out also in the thickness direction).

FIG. 2 shows a schematic drawing showing an example in which electric properties are changed by a shape (in the case of a field effect transistor, a constant state is maintained in the thickness direction (particularly thin cases)).

FIG. 3 shows a schematic drawing showing an example in which electrical property is changed by a shape (in the case of a resistor).

FIG. 4 shows a schematic drawing showing an example of a connection to a different conductor (in the case of a connection to outer wiring).

FIG. 5 shows a schematic drawing showing a form and a manufacturing process in the case of mounting on a substrate with an electrode (an example of a relatively large circuit, in the case of using a printing, etc.).

FIG. 6 shows a schematic drawing showing a form and a manufacturing process in the case of mounting on a substrate having an electrode (an example of a fine circuit, in the case of using processing by beam).

FIG. 7 shows an atomic force microscope image of a bending portion of a thin film particle (the light color part in the right side is a silicon wafer, the bending portion exists in the right and left directions nearly in the center).

FIG. 8 shows an optical microscope image of a processing example of the inside of a particle (the white part is a domain removed by a focussed ion beam).

FIG. 9 shows an atomic force microscope image of a processing example of the inside of a particle (portion which is processed to a square shape).

FIG. 10 shows an atomic force microscope image of a processing example of the inside of a particle (a part of two kinds of lines (zonal structure)).

FIG. 11 shows the structure of a device for measuring mobility.

FIG. 12 shows a current-voltage character in the case of heating-reduction at 300° C. for 240 minutes (with light shielding).

FIG. 13 shows a current-voltage character in the case of heating-reduction at 300° C. for 240 minutes (without light shielding)

FIG. 14 shows a change of an electric current increased-amount immediately after the applying of a gate voltage (N type, with light shielding).

FIG. 15 shows a change of an electric current increased-amount immediately after the applying of a gate voltage (N type, without light shielding).

FIG. 16 shows a change of an electric current increased-amount immediately after the applying of a gate voltage (P type, with light shielding).

FIG. 17 shows a change of an electric current increased-amount immediately after the applying of a gate voltage (P type, without light shielding).

### DETAILED DESCRIPTION OF THE INVENTION

In the present invention, symbols in drawings have the following meanings; 1 substrate in the present invention, 2 insulator part, 3 conductor part, 4 one sheet of thin film particle (oxidized form), 5 one sheet of thin film particle (reduced form), 6 one sheet of thin film particle (oxidized form) of which the inside has a pattern formed, 7 lots of thin film particles having a pattern formed (oxidized form), 8 lots of thin film particles having a pattern formed (reduced form), 10 thin film particle having a pattern formed, 11 semiconductor part (particularly narrow part), 12 conductor part (wiring), 13 conductor part corresponding to a source electrode (broad part ensuring a current quantity in the thickness direction), 14 conductor part corresponding to a drain electrode (broad part ensuring a current quantity in the thickness direction), conductor part (a semiconductor side corresponds to a source electrode), 16 conductor part (a semiconductor side corresponds to a drain electrode), 17 conductor part imparted with high resistance, 18 connection part to outer wiring (broad part ensuring a current quantity in the thickness direction), thin insulator part, 30 conductor part corresponding to a gate electrode (wiring, not the entire surface especially in the case of an integrated circuit, etc.), 40 insulator part, 50 outer conductor part (wiring), 51 highly doped N type silicon wafer (also working as a gate electrode), 52 thermally oxidized film, 53 source electrode, 54 drain electrode, 55 channel layer and 56 electrode for outer connection.

For achieving the above purposes, the present inventors have studied elemental technologies including an improvement in the affinity of a substrate to thin film particles and processing of a specific position of the thin film particles or a lamination layer aggregate formed of the thin film particles or a location of the thin film particles or the lamination layer aggregate into a specific position of the substrate. As a result, the present inventors have found that characteristics of the thin film particles can be effectively utilized. On the basis of the above finding, the present inventors have completed the present invention 1.

The present invention 1 will be explained hereinafter.

(Synthesis of Oxidized Form Thin Film Particles)

The oxidized form thin film particles (oxidized form carbon nanofilm) used in the present invention are selected from thin film particles, as previously disclosed in JP-A-2002-53313, obtained by chemically or electrochemically oxidizing graphite containing only a small amount of impurities and having a well-developed layer structure and high crystallinity as a raw material and then carrying out purification such that small ions, etc., are removed as much as possible, to advance spontaneous layer separation. When the degradation (destruction) of skeleton of each layer is a little, the oxidation time is preferably long, e.g. 30 minutes per 10 μm in length in the planar direction (inplane direction formed by a-axis and b-axis of the raw graphite), for advancing the layer separation as much as possible. Inversely, when the layer separation is possible, the oxidation can be terminated in the shortest time enough to advance the layer separation.

Particularly, when large-scale thin film particles wide in the planar direction are synthesized, as previously disclosed in Japanese Patent Application No. 2001-374537, graphite having a broad planar-direction length, e.g., 1 mm or more, and as thin a thickness (c-axis-direction length) as possible, e.g., 300 μm or less, and having high crystallinity is used as a raw material and the graphite is subjected to oxidation for a long period of time. In this case, stirring of a liquid at the time of synthesis (oxidation and purification) is minimized to prevent each layer from degradation (destruction). Further, the shape of the raw graphite may be processed in advance for obtaining thin film particle having a desired shape (square, etc.)

Furthermore, there is a method in which a dispersion of the thin film particle is heated at about 100° C. as a method for promoting layer separation especially.

As described above, there is synthesized a dispersion of thin film particles having an extremely small thickness, which can be called an oxidized form carbon nanofilm, in water. Concerning the dimensions of the thin film particles, a thin film particle having a relatively small dimensions has a thickness of 0.4 nm to 10 μm (c-axis direction of the raw graphite), preferably 0.4 nm to 5 nm, and a planar-direction size of 20 nm or more (direction of a-axis and b-axis of the raw graphite), preferably 200 nm or more, further preferably 1 μm or more. Further, for example, a large-scale thin film particle has a thickness of 0.4 nm to 10 μm (the nanofilm includes even a thin film particle having a particularly large thickness in consideration of a decrease in thickness by subsequent processing), preferably 0.4 nm to 1 μm, and a planar direction size of 500 μm or more, preferably 3 mm or more. The above dimensions are selected depending upon the uses of the thin film particles.

In the stage where the synthesis of the thin film particles is terminated, the morphology of the thin film particles is a dispersion using water as a dispersion medium. The above dispersion medium of the dispersion can be changed from the water to a high polarity liquid having a relative dielectric constant of about 15 or higher other than water, such as methanol, ethanol, acetone or 2-butanone. As a means of using such a high polarity liquid other than water as a main dispersion medium, there are a method in which the high polarity dispersion medium other than water is added in an amount sufficiently larger than the amount of the water contained in the dispersion to dilute the dispersion and a method in which the high polarity dispersion medium other than water is added, then a supernatant liquid is removed by means of centrifugation and decantation, etc., and these steps are repeated to gradually exchange the dispersion medium from the water to the high polarity dispersion medium other than water.

The thin film particles have high lyophilic (dispersibility, etc.) to high polarity dispersion mediums including water. However, as the concentration of the thin film particles becomes lower, or, in a comparison of two or more different dispersion mediums, as the dielectric constants of the dispersion mediums become lower, the influence of gravity (replaceable with centrifugal force) becomes larger than the influence of electrostatic repulsion, so that the thin film particles have a tendency to precipitate. Further, as the scale of the thin film particles becomes larger, the thin film particles show a stronger tendency to precipitate. However, a case including such particles having a tendency to precipitate is also called a dispersion.

The dispersion of the thin film particles largely varies in flowability depending upon the concentration, since the thin film particles have high anisotropy of shape. For example, a dispersion having a concentration of about 2 wt % does not flow even when a container is inclined, although it depends on the dimensions or shape of the thin film particles contained.

(Synthesis of Lamination Layer Aggregate of Oxidized Form Thin Film Particles)

The thin film particles obtained by oxidizing graphite, used in the present invention, can be selected from graphite oxides obtained according to known methods such as the Brodie method (using nitric acid, potassium chlorate), the Staudenmaier method (using nitric acid, sulfuric acid, potassium chlorate) and the Hummers-Offeman method (using sulfuric acid, sodium nitrate, potassium permanganate). Especially, graphite oxides having a thickness of 0.4 nm to 100 nm and a planar-direction size of 20 nm or more and having a very small number of layers are remarkably useful, since these graphite oxides are easily reduced thanks to their small thickness and no other materials having similar properties and characteristics are found. These graphite oxides can be produced according to the methods of JP-A-2002-53313 and Japanese Patent Application No. 2001-374537 disclosed by the present inventors.

As previously proposed in Japanese Patent Application No. 2001-374538, the lamination layer aggregate of the thin film particles can be synthesized by leaving the before-mentioned dispersion of the thin film particles having a precipitating tendency to allow the thin film particles to precipitate and to generate bonds between a plurality of the thin film particles. Intermolecular forces, a hydrogen bond, a covalent bond due to inter-particle dehydration, etc., are thought as a generated bond. The period of leaving the dispersion is 10 days or more, preferably 30 days or more, when the precipitation is carried out by means of only the gravity. Furthermore, when the precipitation is carried out by means of centrifugal force, the period of leaving the dispersion thereafter can be shortened. Although the concentration of thin film particles to be precipitated in the dispersion depends on the size of the thin film particles to be used, it is preferably roughly 0.1 wt % or lower, more preferably 0.01 wt % or lower. When the precipitation is fast or the concentration is high, a plurality of the particles is brought into contact with each other before precipitating. In this case, fine lamination is difficult so that a lightly turbulent collective matter is formed. Further, when the above concentration is low, a broad collective matter can not be obtained since overlaps of the particles enough to give strength necessary for integration do not occur.

When a liquid containing the lamination layer aggregate is shaken mildly, the lamination layer aggregate floats in the liquid and can exist isolatedly in the liquid. Although the dimensions thereof depend on the size of the thin film particles, the thickness is 10 nm or more, the planar direction size is 100 nm or more, further 100 μm or more. Further, since the above lamination layer aggregate has a large planar-direction size relative to its thickness, it can be intensely bent as if to be nearly broken even though it is composed of thin film particles having a dense carbon skeleton. In this bending part, each of the thin film particles being constituents bends intensely as if to be nearly broken. Furthermore, each fundamental layer, which can be called a large-scale planar molecule, of the thin film particles also intensely bends in this part.

The above lamination layer aggregate is also a carbon nanofilm in a broad sense. However, since it is a secondary structure, it will be treated separately hereinafter and it will be clearly called a lamination layer aggregate of thin film particles.

(Synthesis of Reduced Form Thin Film Particles)

The oxidized form thin film particles can be reduced by various known reduction reactions using a reducing agent or an electrode reaction (electrolytic reduction). However, it is thought that, especially in the case of using the reducing agent, complete reduction including the reduction of the inside of a multi-layer particle is difficult unless its fundamental layers are degraded. On the other hand, it is possible to almost completely reduce even the inside of a multi-layer particle in the case of reduction by heating (J. Maire et al., Carbon, 6, 555 (1968)) known as a general behavior of graphite oxide. The oxidized form thin film particles are converted into reduced form thin film particles by heating, as previously disclosed by JP-A-2002-53313.

Here, when the thin film particles are completely reduced, each fundamental layer of the thin film particles becomes almost graphite's fundamental layer (graphene). The interlayer distance (not defined in the case of single-layer) is almost equal to the interlayer distance of graphite. However, each thin film particle has a structure of a turbostratic tendency in which the mutual positional relationship of respective layers is more turbulent than that of graphite. Further, the mutual positional relationship of a plurality of the thin film particles in the planar direction becomes a very turbostratic (almost random) layer structure. In addition, it is a structure in which gaps are present between a plurality of the particles.

On the other hand, it is not necessarily required that the reduction degree of the thin film particles is complete. Partial reduction is acceptable so long as the electronic nature, etc., can be stably utilized. In this case, each fundamental layer contains oxygen, etc., and its interlayer distance is larger than that of graphite.

Reduction by heating rapidly arises at especially about 150° C. to 200° C. In addition, it proceeds mildly up to 1,000° C. or higher under a nonoxidative atmosphere or in vacuum. Further, it is expected that the thin film particles become larger crystals by pressurization at a high temperature. On the other hand, the thin film particles are burnt down at 600° C. or lower in the air so that only partial reduction where oxygen, etc., slightly remain is possible. In the reduction by heating, water, oxygen, carbon compounds, etc., are eliminated. As a result, the content of oxygen changes from approximately 40 wt % before the reduction to 0 to 35 wt %. Since oxygen, etc., are eliminated by the reduction, the thickness of each thin film particle decreases. In contrast, the planar-direction size of the thin film particle does not change so much. This is understandable since the nearest carbon-carbon distance in a planar skeleton (corresponding to graphene) constructed by sp² carbon is 0.142 nm, the nearest carbon-carbon distance in a zigzag planar skeleton (please suppose a skeleton obtained by taking out only a (111) face of a cubic diamond) constructed by sp³ carbon, which distance is projected on the (111) face, is 0.145 nm, and the nearest carbon-carbon distance in a case containing both sp³ carbon and sp² carbon is between the above values. Due to the above smallness of the changes, peeling does not occur easily in reduction on a substrate, which will be described later.

As described above, the reduced form thin film particles (reduced form carbon nanofilm) are synthesized from the oxidized form thin film particles (oxidized form carbon nanofilm) by heating at a relatively low temperature. Similarly, the lamination layer aggregate of the reduced form thin film particles is synthesized from the lamination layer aggregate of the oxidized form thin film particles.

(Structural Characteristics of Thin Film Particles)

In the thin film particles synthesized as above, each layer thereof has a carbon skeleton of high periodicity. Particularly, the reduced form thin film particle has a structure in which the skeleton has many pi electrons. For this reason, electronic development is possible. Particular, when a novel electronic property (described later), which emerges in a fine structure of a carbonaceous material, is used, a structure like a reduced form thin film particle having high periodicity and containing a broad carbon skeleton is the most suitable. Further, particularly, the oxidized form thin film particles have a polar functional group and have lyophilic to many liquids. Therefore, a thin structure material of a carbonaceous material, which is generally difficult to handle, can be easily handled in the form of dispersion.

(Electronic Characteristics of Thin Film Particles)

When the thin film particles (carbon nanofilm) are compared with a carbon nanotube which is expected as a electronic nanomaterial, advantages are as follows. It is possible to locate complicated wiring or a device consisting of a lot of parts spreading two-dimensionally and further three-dimensionally in a lump by post-processing (in the case of nanotube, it is required to individually locate a plurality of nanotubes). It is possible to freely set an area to be in contact with an outer electrode (in the case of nanotube, the contact area is small, which may cause high resistance). It is possible to freely set a line width at the time of processing (in the case of nanotube, it is required to select it by thickness and a plurality of nanotubes are required for a particularly thick line). However, the carbon nanotube and the carbon nanofilm are not mutually exclusive. Novel uses are possible by combining both of these or further combining other materials with these.

(Changes by Fine Structuring)

Concerning electronic conduction in a solid, when the dimensions of the solid are fine, changes occur such as ballistic conduction (electrons move to a proper distance without undergoing scattering), a quantum interference effect (electric conductivity varies by phase difference in electron waves) and a quantum size effect (discretization of an energy level occurs because of electron confinement and the band state of electrons can be controlled by a material and dimensions). Concerning the reduced form thin film particles also, fine processing can brings about such changes. Here, for example, the quantum size effect generates when the dimensions of a material are almost equivalent to or less than a wavelength as a wave of an electron. Conventional observations of the quantum size effect have been carried out by using various semiconductors which have an electron wavelength of approximately several tens nm or more and are easy to process, rather than metals which have a small electron wavelength of approximately 1 nm and are relatively difficult to process. In contrast, though the reduced form thin film particles are a material having a relatively high conductivity, they have a possibility of exerting a quantum size effect in large dimensions (particularly a planar-direction dimension).

On the other hand, multi-layer thin film particles in reduced form have a particularly lower electric conductivity in the interlayer direction as compared with in the planar direction (intralayer direction). For this reason, the influence of the thickness upon electric properties is generally low except for cases where the thickness is very thin (e.g., 10 nm or less). The above multi-layer thin film particles may be treated as if electrically independent layers are stacked. For this reason, it is possible to secure a current quantity by a proper thickness (the number of layers) together with using various changes due to fine structuring in the planar direction.

(Use of a semiconductive property, etc.)

It is known that graphite oxide increases in electric conductivity by several digits or more when subjected to heating-reduction (J. Maire et al., Carbon, 6, 555 (1968), this document is silent on the thickness of a particle, while it is not so small). The oxidized form thin film particles undergo a change similar to the above change. Such a change from a semiconductor region to a conductive region generates because heating causes elimination of OH groups, etc., and the ratio of sp² carbon in the carbon skeleton is increased at the same time. This change can be controlled by temperature. However, since the stability of a structure containing OH groups, etc., is low, inversely, a thermal influence is apt to occur.

Therefore, it is not desirable to use the above semiconductor region, as it is, in an electronic circuit or a device which is required to have reliability for a long period of time. In contrast, as a method for stabilizing a semiconductor region (more generally, a method for changing electric properties or a method for developing a property specific to a fine structure as a special case of this change), thinkable are the use of a chemical change, the use of an influence from outside sources, the use of shape processing, etc., described hereinafter.

The stabilization of the semiconductor region by chemical changes such as modifying or modification (further, a method for changing electric properties) is actualized by introducing a stable other structure for keeping sp³ state as part of a lot of carbons in the carbon skeleton (the sp³ carbons are kept so as to coexist with sp² carbons, since the carbon skeleton becomes a nonconductor when all carbons are changed to sp³ state). Light elements which are thought to be introducible by a chemical reaction in a liquid phase or a gas phase for the stabilization include hydrogen (partial hydrogenation, in some cases a p type semiconductor is obtained), fluorine (partial fluorination, ditto), and the like. Here, for a position-selective introduction for manufacturing a device or the like, the thin film particles are mounted on a substrate and a mask is used in combination (resist work, etc.). Moreover, when it is allowed to partially change the carbon skeleton, a method which enables the position-selective introduction includes irradiation (injection) of an ion beam or a neutral particle beam. These enable a removal of part of carbons (formation of a fine porous structure) or an introduction of a heteroatom (if possible, a heteroatom which increases a carrier too) such as boron or nitrogen. Further, when the raw material is not limited to graphite, it is thinkable to produce thin film particles from carbonaceous multi-layer structure materials containing a heteroatom (boron, nitrogen, etc.).

The stabilization of the semiconductor region by the use of influence from outside sources (further, a method for changing electric properties) can be actualized by using a change of the electric properties of the thin film particles by a substrate. For example, when a substrate of a high dielectric-constant material, particularly such as a polarized electret, having high electron donating property or accepting property is used, an effect of generating a carrier, analogous to chemical doping, is expected. Further, the use of a field effect, described later, is thinkable.

The stabilization of the semiconductor region by shape processing (further, a method for developing a property specific to a fine structure) is mainly actualized by fine processing of the thin film particles after complete reduction. Recent study conclusions of various carbonaceous condensed-ring materials can be used for the above stabilization. Such carbonaceous materials are shown below from materials having a narrow width to materials having a large width in order. The carbonaceous materials include a linear carbonaceous material (one-dimensional: polyacetylene), a zonal carbonaceous material (1.5-dimensional: polyacenes in the wide sense (polyacene series, polyphenanthrene series, etc.), a zonal carbonaceous material having a broader width is called nanoribbon) and a planar carbonaceous material (two-dimensional: graphite (graphene in the case of one layer)). It is estimated that these carbonaceous materials come to have a narrower band gap in accordance with an increase in width, and that the band gap changes according to the crystal orientation of the carbon skeleton (for example, K. Tanaka et al., Synthetic Metals, 17, 143 (1987), however, this estimation concerns the structure of hydrocarbons, i.e. carbonaceous materials terminated with hydrogen). Concerning the planar carbonaceous material, when a plurality of one-layer graphenes (graphene is estimated to be a semiconductor having a band gap of 0) are regularly laminated (graphite), electric conductivity comes out (in the case of a few layers, the electric conductivity changes in stages) as influences of the number of layers and a laminating state. In contrast, when a plurality of one layer graphenes are randomly laminated (turbostratic structure carbon), it is estimated that the graphenes become a semiconductor having a band gap of 0. As described above, regarding a zonal structure, there is a possibility that electric properties typified by a semiconductive property can be freely controlled by its width, thickness (the number of layers), crystal orientation of the carbon skeleton, laminating state, kind of a terminal bond, and the like. The above possibility is not limited to the thin film particles after complete reduction. It is common to carbonaceous condensed-ring materials having a large scale and high periodicity. Generally, it does not depend on a manufacturing method (it is not required to pass the oxidized form thin film particles).

When the thin film particles (particularly thin film particles which are a single crystal having a broad area) are used as raw materials, it is easy to concurrently fabricate a plurality of such structures of which the electric properties can be freely controlled, by fine processing. Completely removing carbons in a selected position or thinning enables the fabrication of a desired circuit or device. Further, it is thinkable to use a plurality of such structures for increasing a current quantity in a structure having a narrow width (however, when a loop is formed, an oscillating phenomenon occurs in some cases), to meander path for imparting high resistance, or to make holes periodically.

Up to now, as described above, no 2˜2.5-dimensional, large scale and high periodic carbonaceous structure matter, such as the thin film particles (carbon nanofilm), from which an arbitrary 1.5-dimensional structure in planar direction can be extremely easily made, has been known. In addition, a concrete processing principle has not been proposed.

(Improvement in Electric Conductivity)

Characteristics of the electric conductivity of the reduced form thin film particles (reduced form carbon nanofilm) are similar to those of a general molecular material. The characteristics are that the density (number per unit volume) of carriers (electron or hole) is relatively low and that the interlayer or inter-particle electric conductivity corresponding to intermolecular electric conductivity is lower than the intralayer electric conductivity corresponding to intramolecular electric conductivity. Therefore, when an increase in the electric conductivity is desired, inversely, it is preferable to increase the density of carriers or increase the interlayer or inter-particle electric conductivity.

A method for increasing the density of carriers includes a conventionally known chemical doping in the first place. In this case, however, a generated intercalation compound is generally instable in the air so that it is difficult to use the intercalation compound stably for a long period of time. In addition, there is a method called a field effect doping in which charges are generated in an insulator part neighboring to a part which is desired to be imparted with high conductivity and then the charges are injected, as carriers, into the part which is desired to be imparted with high conductivity (for example, A. Tsumura et al., Appl. Phys. Lett., 49, 1210 (1986)). There is an example in which a collective matter (crystal, etc.) of molecular materials is brought into a high conductive state (superconductive state at a low temperature) by the above method (for example, J. H. SchÖn et al., Science, 288, 656 (2000)). In this case, although a different part for generating charges is necessary, stable use for a long period of time is possible. Further, if the collective matter is used in a semiconductor region, it is possible to change the collective matter to either of n type (electrons are carriers) and p type (holes are carriers). By using this method for the reduced form thin film particles, an appearance of a superconductive state in a low temperature range and an improvement in electric conductivity in an ordinary temperature range (further, superconductivity) are expected. The reduced form thin film particles are the most suitable as an object of field effect doping of a graphitic material thanks to the highness of periodicity of each layer, the shape and the highness of adhesion to a substrate.

For increasing the interlayer or inter-particle electric conductivity (relatively decreasing the influence of the interlayer or inter-particle electric conductivity), it is important that a particle having as large a size as possible is isolatedly used or a small number of such particles are used such that the inter-particle electric conductivity does not become a problem. When a lot of particles are used, it is important that the particles are regularly laminated with a small gap. For further increasing the electric conductivity, it is thinkable to form sigma bonds and pi bonds between different particle layers present at the same positions in the thickness direction or to form sigma bonds and pi bonds between laminated layers by lightly destroying the respective laminated layers to such an extent that the interlayer electric conductivity does not decrease so much. Heating in a nonoxidative atmosphere at a high temperature, turning on electricity, irradiation of an ultraviolet light or a particle beam, etc., can be used for forming these bonds.

(Application to Electronic Circuit or Device)

Objects of applications of the oxidized form and reduced form thin film particles (an isolated particle or a plurality of particles) to an electronic circuit or a device are roughly divided into two categories for a large-scale circuit and for a fine circuit. Further, the form of the use of the thin film particles is roughly divided into two forms of isolated or a small number of large-scale particle(s) and extremely many fine thin film particles. Combinations of these are as follows.

The application object for a large-scale circuit particularly includes a conductor part of a high temperature semiconductor device (a semiconductor part is diamond, silicon carbide or the like) whose development in the future is expected. Such a device is expected to have high temperature resistance (up to approximately 500° C.), high power and radiation resistance and further expected to perform high-speed operations in the future. Further, an application for an ultraviolet-light-emitting device has been partially substantiated. In this application, the device has a conductor part having a relatively wide line width, such as 1 μm or more or 1 mm or more. Further, it is estimated that a large conductor part has a broad area of several cm² or more. For the above application, the thin film particles are suitably used in any form of an isolated large-scale particle, a small number of large-scale particles and extremely many fine thin film particles. Among these, when the extremely many fine thin film particles are used, it is possible to form a conductor part with low anisotropy from a macroscopical perspective, particularly, in a broad area portion or a long portion. In this case, it is required to pay attention to relatively low electric conductivity because of the absence of a broadly continuous layer and the presence of voids and to variations in thickness by positions.

The application object for a fine circuit particularly includes an element main body or a conductor part of a high-speed or specific device whose development in the future is expected. Ultrahigh speed operations, high integrating and, further, quantum calculation (multiplexed operation capable of solving a combination problem at high speed) are expected of such a device. In this application, an element main body or conductor part having a narrow line width of 1 μm or less or 10 nm or less is important. At the same time, a broad line width is necessary in a connection part to the outside. Further, a discontinuous layer, voids, variations in thickness by positions (except for variations in thickness given by processing), etc., are undesirable in an element main body or conductor part having a narrow line width which has a function, and a layer constructed by a continuous carbon skeleton connected by covalent bonds is necessary. In addition, as broad an area as possible is preferable for forming an integrated circuit or for mass production. As a result thereof, the form of the thin film particles suitable for this application is mainly an isolated large-scale thin film particle or a small number of large-scale thin film particles. However, a little limitation is imposed on a used direction by anisotropy of the carbon skeleton (for example, when a narrow zonal shape is formed, the electric conductivity varies depending upon the crystal orientation of the skeleton).

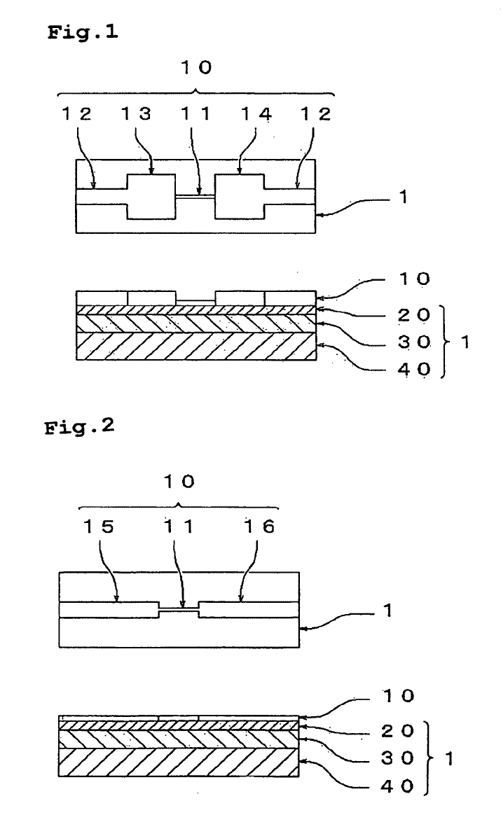

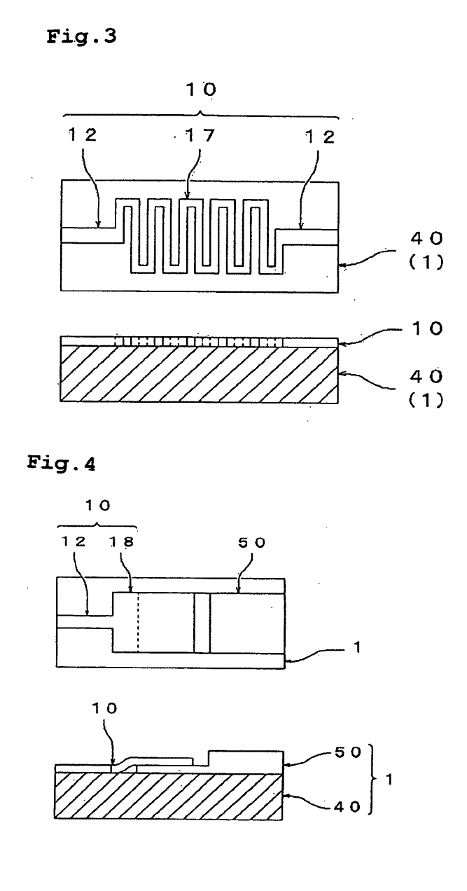

As described above, it is possible to produce discrete devices such as a transistor (particularly a fine transistor for single electron), a resistor and a capacitor or a wiring part by using the thin film particles in combination with a different insulator, semiconductor or conductor. Further, it is possible to produce an integrated circuit of these (FIG. 1, FIG. 2, and FIG. 3).

Even when the thin film particles are completely reduced, they have a lower electric conductivity in comparison with, for example, copper, unless the before-mentioned field effect doping, etc., is not carried out. In addition, when a lot of the particles are used, the influence of a boundary is added so that the resistance in a long conductor part becomes high. Therefore, it is preferred to limit the use of such a circuit using the thin film particles as above to a part to be subjected to a particularly high temperature or high speed, if possible. Inverse to metals, the thin film particles increase in electric conductivity under a high temperature state and are stable at high temperatures so that the thin film particles are suitable for high temperatures.

Further, the electric conductivity of the thin film particles in the thickness direction is lower than the electric conductivity thereof in the planar direction. For this reason, it is preferred to adopt a shape design for anisotropic materials in electric circuits and devices using the thin film particles, e.g. to secure a current quantity in the thickness direction by disposing a broad area portion at each key point (FIG. 4).

(Use of Substrate and Improvement in Its Affinity)

As for the above various applications of the thin film particles, it is necessary to carry out processing with defining the size and shape in the planar direction for obtaining the reproducibility of electric properties or the like. At the time of the processing or an actual use in a device or the like, it is difficult to float the thin film particles stably in space for a long period of time or the reliability is decreased. Further, it becomes important to use the thin film particles in combination with a different specific kind of material. For these reasons, the thin film particles are mounted on a proper substrate of a different material or held inside a matrix of a different material. Among these, the method of mounting the thin film particles on the substrate is important in particular.

The kind of the substrate can be selected from known various materials. However, it is preferable to use a substrate from an insulator to a semiconductor and a stable substrate additionally having heat resistance to about 300° C. or higher, since possibilities are expanded by combining a material having properties (electric properties, optical property, etc.) different from those of the thin film particles and reduction by heating is necessary or a device or the like is used at a high temperature in some cases according to uses. The material thereof is selected from inorganic compounds and organic compounds. The inorganic compounds include silica, alumina (sapphire), silicon, diamond, silicon carbide, borosilicate glass and aluminosilicate glass (non-alkaline glass) and the like. The organic compounds include various heat-resistant resins such as an epoxy resin and polyimide. Further, there may be used substrates treated by known various treatments such as impurity doping in a semiconductor use, a substrate of a composite such as fiber-reinforced plastics, and a multi-layer substrate obtained by mounting a thin insulator on a substrate made of a different material such as a metal. Further, there may be used a stretchable substrate which can change the electric properties, etc., of the thin film particles, a porous substrate, and a substrate having fine roughness.

As for the shape of the substrate, generally, a planar shape is easy to handle, while a three-dimensional shape may be used. In the case of any shapes, the formation of a pattern is possible by, for example, using the thin film particles in the form of dispersion, as described later.

When the thin film particles are mounted on the substrate, the oxidized form thin film particles are easy to handle. In this case, for keeping the adherence of the thin film particles on the substrate stably, including that at the time of using after processing, it is preferred to improve the substrate in affinity before mounting the thin film particles. This corresponds to an increase in the polarity of the substrate surface. It is actualized by increasing the density of functional groups on the substrate surface.

A concrete method for the above affinity improvement includes a chemical treatment using an acid or alkali and a physical treatment using heat, plasma or a variety of beams. In particular, judging from the present inventors' tests using various inorganic compound substrates, a simple heat treatment of approximately 300° C. or higher was effective. Further, it was desirable to wash the substrates as far as possible before the heating and immerse the substrates in water after the heating. It is estimated that this is an effect of removal of organic compounds adhering to the surface and an effect of generation of oxide, a hydroxyl group or the like due to the oxidation of the surface.

The extent of the affinity improvement of the substrate can be evaluated according to, for example, a contact angle to water. The contact angle is 40 degree or less, preferably 20 degree or less, for mounting the thin film particles.

(Manner of Mounting Thin Film particles on Substrate)

Generally, a dispersion of the oxidized form thin film particles is used for mounting the thin film particles on the substrate (surface). In the case of thin film particles having a size of approximately several hundreds μm or less, a manner in which a dispersion containing relatively many particles is mounted on the substrate is easy. In the case of thin film particles having a larger size, easy is a manner in which respective particles are recognized and a small number of the particles, such as one particle sheet, are mounted on the substrate. Of course, the inverse combinations of these are also acceptable. When a fine device or wiring, etc., is produced, generally, the thin film particles are mounted on the substrate such that the particles are not in contact with each other. Therefore, a small number of the thin film particles are mounted. When a large-scale wiring, etc., is produced, the thin film particles are mounted on the substrate such that the particles are brought into contact with each other. Therefore, a lot of the particles are mounted at the same time.

The concentration of the dispersion for mounting the particles on the substrate may be altered depending upon the number of the particles necessary at the time of using, like above. In addition, a concentration, which can give a viscosity (flowability) which is easily used in pattern formation described later, is sufficient. Further, other components may be added for adjusting the viscosity.

As described before, the dispersion medium for the dispersion used for mounting the particles on the substrate can be selected from high polarity liquids having a relative dielectric constant of about 15 or higher. When the dispersion medium is required to have a fast drying speed or a small surface tension, methanol, acetone or the like is particularly preferred. Accordingly, well-stretched particles having few wrinkles can be mounted on the substrate in a short time. However, there is a possibility that the electric conductivity is actively changed by wrinkles (meanders in the thickness direction).

When a lot of the thin film particles are mounted on the substrate, the planar-direction size and thickness of the whole of a lot of the thin film particles are decided such that a desired shape or desired electric conductivity of wiring or the like can be obtained. However, when the planar-direction size is too large or the thickness is too large, a long time is necessary for escape of the dispersion medium or eliminating water at the time of drying of the dispersion medium and at the time of reduction by heating. Further, when a temperature-increase is too fast at the time of drying or at the time of reduction by heating, the dispersion medium or water rapidly vaporizes, which causes peeling at an interface between the substrate and the thin film particles or at a boundary between the thin film particles. For this reason, it is preferable to increase the temperature at a low speed (e.g., 10° C./hour or less). Further, a shape which is not too wide as much as possible or a shape which is wide but has properly macroscopic holes is preferred for decreasing the escape distance of a gaseous body, and a shape which is not too thick as much as possible is preferable for decreasing the generation amount of a gaseous body per unit area.

(Addition of Different Conduction Parts, Etc.)

It is not preferable to use the thin film particles in a large (long) portion in an electronic circuit or a device, since the electric conductivity of the thin film particles is generally low even when the thin film particles are completely reduced, as described before. For this reason, it is preferable to use a metal having electric conductivity higher than that of the thin film particles, as a different conducting material, in a different conduction part such as a connection part to the outside. In this case, when stability at high temperatures is necessary, gold or the like is used. When high temperatures are not necessary, copper, aluminum or the like is used.

Such a different conduction part or a semiconductor part or insulator part which constitutes a different device may be previously added on the substrate before the thin film particles are mounted on the substrate. Here the term “substrate” includes these parts. However, when such a different part is thick and differences in level exist, there is a possibility that the differences in level cause peeling of the particles from the substrate or cracking of the particles. Particularly, this is a problem in respect to large-scale particles. In this case, it is effective to thin the structure of the different conductor part, etc., as far as possible, to form a different conductor part having a buried damascene structure, or to add different parts after mounting the thin film particles.

Further, since the anisotropy of electric conductivity of the thin film particles enlarges resistance in a contact zone with the different conductor part or the like, it is preferred to increase a contact area at that part.

In regard to applications to an optical device or a recording material, generally, no connection part to the outside is necessary.

(Pattern Formation Method)

For mounting the thin film particles on the substrate, a conductor for connection to the outside or the like in a predetermined position, the present system is combined with one or more known various pattern formation methods. In this case, particularly, pattern formation using the oxidized form thin film particles which can be treated in the form of dispersion is advantageous.

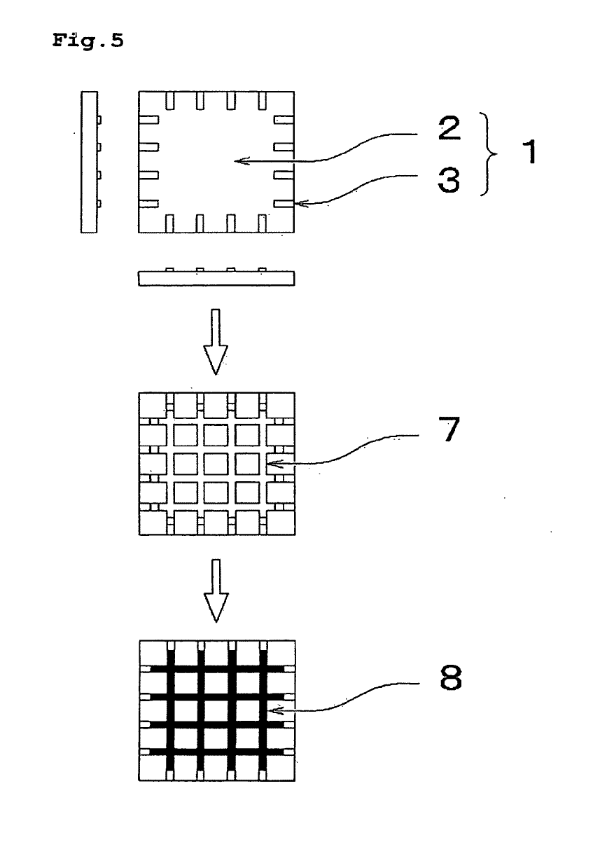

In the case of a relatively large-scale pattern, for example, the pattern can be formed by laying a dispersion of relatively small thin film particles, as an ink, at a predetermined portion of the substrate surface by a general printing or coating method such as a screen printing method or an inkjet method and then drying a dispersion medium (the pattern is formed by a portion where the dispersion is laid and a portion where the dispersion is not laid, FIG. 5). In this case, the viscosity of the dispersion is important. For example, a relatively high viscosity (e.g., a degree at which the dispersion does not flow even when inclined) is preferable in the screen printing method. Inversely, a low viscosity is preferable in the inkjet method. Further, it is possible that, after the thin film particles are mounted on the entire surface of the substrate by spincoating, etc., a pattern is formed by performing a lithography using a resist and a mask (mainly exposed by a visible light), etching an unnecessary thin film particle portion and removing the resist. Otherwise, the pattern formation can be carried out by mechanical cutting and grinding.

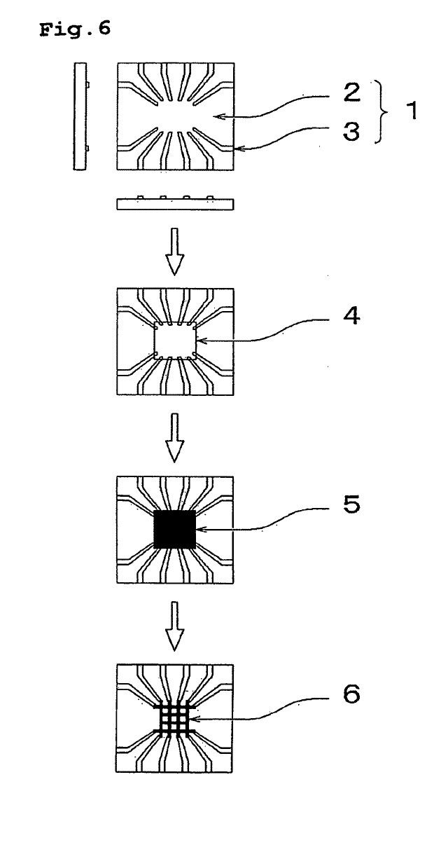

In the case of a small-size fine pattern, for example, an isolated relatively-large thin film particle or a small number of relatively-large thin film particles together with a small amount of a liquid are laid on the substrate and, after the liquid is dried or further reduction is carried out by heating, etc., a pattern is formed by performing a lithography using a resist or a resist and a mask (exposed by ultraviolet light, an electron beam or an ion beam (when no mask is used, scanning of these is acceptable), etching an unnecessary portion inside the thin film particle(s) and removing the resist (FIG. 6). Further, the inside of the thin film particle(s) can be directly etched by scanning of a short wavelength laser, an electron beam, an ion beam, a neutral particle beam, etc., without using the resist. In addition, various processings using a scanning probe microscope (manipulation of molecules or many atoms, further atomic manipulation) are adoptable.

The above pattern formations of the thin film particles can be combined with the addition or pattern formation of a different conduction part or insulating part. In addition, the above various steps can be repeated several times.

(Others)

Electronic circuits or devices using the thin film particles are soft and fragile. However, a general semiconductor device is remarkably fragile when it is particularly fine. Therefore, it is estimated that protection by a similar sealing method is sufficient. Further, even when processing is further carried out after the formation of electric circuit or device using the thin film particles, it is sufficient to provide proper protection. However, in the case of a particularly fine device, there increases a possibility that influences from outer sources (radiation, heat, etc.) cause a disturbance in information. Therefore, further strict protection or adopting a circuit of decision by majority, which perform the same arithmetic operations simultaneously, is desirable.

Since the above electronic circuit or device is formed by deposition (stack) of the thin film particles, voids between the particles remain even after the reduction. For this reason, the electric conductivity varies due to adsorption of small molecules when it is used at a low temperature. However, since no adsorption occurs when it is used at a high temperature, stable working is possible. As a method of removing the influence of the adsorption at a low temperature, for example, it is thinkable to fill the voids with a different insulator or to use a sealed container with hermetic terminals.

It is preferable to use clean raw materials and chemicals and carry out workings in a clean environment in the above steps of from the synthesis of the thin film particles to the fabrication of an electric circuit or device. When particularly fine processing is carried out, it is required to avoid contamination of a fine dust or the like as far as possible, so that workings in a clean room are desirable.

The present invention 2 will be explained hereinafter.

The present invention 2 provides a method for reducing thin film particles which are obtained by oxidizing graphite, are dispersible in a liquid having a relative dielectric constant of 15 or higher and have a carbon skeleton, comprising irradiating the thin film particles with light and a method for forming a thin-film layer formed of the above thin film particles.

The present inventors have noticed that the above thin film particles have photoabsorption in a wavelength range including an ultraviolet region and a visible region and irradiated a thin film layer formed of the thin film particles formed on a substrate with light. As a result, the present inventors have found that the thin film particles are reduced. Furthermore, it is found that, when the thin film particles in the state of a dispersion thereof in a liquid are irradiated with light, the thin film particles can be reduced with holding a high disperse state. On the basis of these findings, the present inventors have completed the present invention.

That is, the present invention 2 is directed to a method for reducing thin film particles which are obtained by oxidizing graphite, are dispersible in a liquid having a relative dielectric constant of 15 or higher and have a carbon skeleton, which method is characterized in that the thin film particles are irradiated with light. Preferably, there are used thin film particles having a thickness of 0.4 nm to 100 nm and a planar-direction size of 20 nm or more each. Further, when the thin film particles are reduced according to the present invention 2, the resistivity of the thin film particles after heating can be decreased down to 10,000 Ω·cm or less so that the thin film particles can be applied to various fields as a semiconductor or a conductor.

The wavelength of light used for the light irradiation in the present invention is preferably in the range of from 100 nm to 1,100 nm. A usable light source includes an ultrahigh pressure mercury lamp (280 nm to 600 nm), a xenon lamp (300 nm to 1,000 nm), a deuterium lamp (110 nm to 600 nm), an argon gas laser (351 nm to 515 nm), a helium-neon gas laser (633 nm), a YAG laser (1,060 nm), various excimer lasers (F₂: 152 nm, ArF: 193 nm, KrF: 249 nm, etc.) and various semiconductor lasers having a wavelength range of approximately 600 to 1,100 nm.

When the present invention 2 is applied to the thin film layer formed of the thin film particles formed on the substrate, there are carried out a step of forming a thin film layer of thin film particles, which are obtained by oxidizing graphite, are dispersible in a liquid having a relative dielectric constant of 15 or higher and have a carbon skeleton, by applying a dispersion of the thin film particles in a liquid to a substrate and then a step of irradiating the entire surface of the thin film layer or selectively a desired portion of the thin film layer with light, whereby a desired reduced thin film layer pattern can be formed in the thin film layer.

Further, the thin film particles can be reduced with holding a high disperse state by irradiating the dispersion of the thin film particles in the liquid with light. As a dispersion medium used for the light irradiation to the dispersion, a liquid having a relative dielectric constant of 15 or higher is isolatedly used. Otherwise, two or more liquids are mixed and the mixture is used as the dispersion medium. In the latter case, a liquid having a relative dielectric constant of less than 15 may be partially used.

Further, there is a specific example of the reduction by light-irradiation. In this example, a liquid containing at least 10% of a liquid having a relatively-small relative dielectric constant of 10 to 35 is used as a dispersion medium for the thin film particles, the thin film particles are reduced by light-irradiation, and then, the resultant dispersion is dropped into a high polarity liquid having a relative dielectric constant of 40 or higher, whereby a homogeneous film formed of the thin film particles can be formed on the liquid surface. By transferring the above thin film to a substrate surface, a thin film layer having remarkably high uniformity can be formed on the substrate surface. This utilizes the following phenomenon. The thin film particles change in the affinity to a liquid in accordance with the reduction and come to have affinity to a lower polarity liquid rather than a high polarity liquid. Therefore, at the time when a low-polarity dispersion is introduced into a high polarity liquid, a dispersion medium in the low-polarity dispersion dissolves in the high polarity liquid, while the reduced thin film particles float on the liquid surface since the reduced thin film particles have low affinity to the high polarity liquid.

Then, the present invention 3 will be explained hereinafter.

The present invention 3 provides a semiconductor device comprising a substrate, a semiconductor layer formed on the substrate, and a junction for feeding an electric current to the semiconductor layer, wherein the semiconductor layer is formed of thin film particles obtained by oxidizing graphite.

The thin film particles can be widely changed in electric conductivity and can be used in broad fields from a semiconductor to a conductor. Further, these thin film particles are obtained in the form of a dispersion thereof in a high polarity liquid so that a film can be formed on the substrate by using a technique such as spincoating, screen printing or inkjet printing. The thin film particles have a characteristic feature in that the film formation is easy.

In addition, the present inventors have carried out characteristic evaluations concerning thin film particles, which are obtained by oxidizing graphite, are dispersible in a liquid having a relative dielectric constant of 15 or higher and have a carbon skeleton, from various aspects and found that particles obtained by heating the thin film particles have high mobility and work as an ambipolar. On the basis of the above finding, the present invention 3 has been completed.

The thin film particles used in the present invention 3 are thin film particles which are obtained by oxidizing graphite, are dispersible in a liquid having a relative dielectric constant of 15 or higher and have a carbon skeleton. In addition, the thin film particles preferably have mobility of 10⁻⁶ cm²V⁻¹s⁻¹ or more. Further, the thin film particles preferably have a thickness of 0.4 to 30 nm each.

### EFFECT OF THE INVENTION

The structure matter composed of the thin film particles having a carbon skeleton (carbon nanofilms in oxidized form and in reduced form) and the substrate on which the thin film particles are mounted, provided by the present invention, is a novel system that can easily utilize the electronic nature or stability peculiar to a carbon material having a periodic structure. It can be applied to fine circuits (device or wiring), circuits for high temperatures (device or wiring), opto-electric conversion devices (solar cell, light-emitting device, etc.), exothermic matters, optical devices, stable recording materials and the like.

According to the present invention, the thin film particles obtained by oxidizing graphite can be reduced by a simple and clean method. The reduction gives thin film particles having high electric conductivity and the thin film particles are remarkably useful as a conductor or a semiconductor in various uses.

Further, the thin film particles having a carbon skeleton, provided by the present invention, have high mobility and function as an ambipolar. Further, an economical technique such as spincoating, screen printing or inkjet printing can be used for the formation of a film. The obtained film is almost free from the occurrence of pinholes and structurally stable and has high heat resistance. From these characteristics, various high functional semiconductor devices can be actualized.

The present invention will be explained more in detail with reference to Examples hereinafter, while the present invention shall not be limited to these Examples.

### Example 1

### Production of Oxidized Form Thin Film Particles Having a Planar-Direction Size of About 20 μm

10 g of natural graphite (supplied by SEC Corporation, SNO-25, purity 99.97 wt % or more, a refined article from which impurities, etc., were removed by heating at 2,900° C., average particle diameter 24 μm, particle diameter 4.6 μm or less 5 wt % and particle diameter 61 μm or more 5 wt %) was added to a mixed liquid containing 7.5 g of sodium nitrate (purity 99%), 621 g of sulfuric acid (purity 96%) and 45 g of potassium permanganate (purity 99%), and the mixture was allowed to stand at about 20° C. for 5 days with stirring mildly, to obtain a high viscosity liquid. The high viscosity liquid was added to 1,000 cm³ of 5 wt % sulfuric acid aqueous solution (water having conductivity of less than 0.1 MS/cm was used for dilution (the same hereinafter)) over about 1 hour with stirring, and the resultant mixture was further stirred for 2 hours, to obtain a liquid. 30 g of hydrogen peroxide (30 wt % aqueous solution) was added to the above liquid and the mixture was stirred for 2 hours.

The resultant liquid was poured to a centrifugal bottle and then centrifugation (maximum radius of rotation 17 cm (the same hereinafter), 1,000 rpm, 10 minutes) was carried out. A supernatant liquid (including a little amount of precipitation, the same hereinafter) was removed to leave a precipitation alone. Further, a mixed aqueous solution of 3 wt % sulfuric acid/0.5 wt % hydrogen peroxide (about 6 times˜about 4 times the precipitation, the magnification decreased as procedures advanced) was added to the precipitation in the centrifugal bottle. Then, the centrifugal bottle was covered with a lid. The bottle was shaken to re-disperse the precipitation. Centrifugation (3,000 rpm, 20 minutes) was carried out and a supernatant liquid was removed. The above procedures were repeated 15 times. The mixed aqueous liquid was used in a total amount of about 13 kg.

Procedures of redispersing, centrifugation (7,000 rpm, 30 minutes) and removal of a supernatant liquid were similarly repeated two times except that the liquid to be added was replaced with water. Further, water was added to carry out redispersing. The resultant mixture was allowed to stand for 1 day, to precipitate only a small amount of easily-precipitable particles (thick particles, etc.). The above precipitated particles were removed and the remaining liquid, which was not precipitated, was subjected to centrifugation (7,000 rpm, 30 minutes) to remove a supernatant liquid. The liquid other than the supernatant liquid consisted of a precipitation, which was not easy to flow, in a lower side and a liquid having a little high viscosity in an upper side. The total amount was about 650 cm³.

The above precipitation which was not easy to flow and the liquid having a little high viscosity were stirred to form a homogeneous liquid. About half of the homogeneous liquid was used, and water (about 5 times˜0.4 times, the magnification decreased as operations advanced) was similarly added thereto. Procedures of redistribution, centrifugation (7,000 rpm, 60 minutes) and removal of a supernatant liquid were repeated 20 times in total. Then, a small amount of water was added and the resultant mixture was stirred, to obtain 1,350 cm³ of an aqueous dispersion of highly purified thin film particles. From a weight change of part of the dispersion before and after drying, the concentration of the thin film particles in the dispersion was 0.45 wt %. Further, according to an elemental analysis of the thin film particles after drying at 40° C. in vacuum, the content of oxygen was about 42 wt % and the content of hydrogen was about 2 wt %.

The above-obtained aqueous dispersion was laid on a glass plate. The dispersion was dried and then it was subjected to an X-ray diffraction measurement. A peak corresponding to 0.83 nm was obtained. This corresponds to a generally known interlayer distance of graphite oxide (when water is held in an interlayer).

The same aqueous dispersion was diluted with water by 100 times. Then, the diluted dispersion was laid on a glass plate and then dried. An attempt to obtain an average value of the thickness of the thin film particles was carried out. When the average thickness of a plurality of particles adhering to the glass plate from the dispersion by drying was calculated at about 12 nm (the density of the particles was assumed 2.1 g/cm³), it was observed through an optical microscope (OM) that almost three sheets of the particles were stacked in all portions of the surface where the dispersion extended (although the particles were extremely thin, they could be discriminated since the reflective index thereof was higher than that of the glass). Accordingly, it was estimated that the respective thin film particles had a thickness of less than 4 nm on average. Further, it was confirmed from the above observation that the average planar direction size of the thin film particles was about 20 μm.

(Production of Oxidized Form Thin Film Particles Having a Planar-Direction Size of About 2 μm or Less)

Small natural graphite (supplied by SEC Corporation, SNO-2, purification product, average particle diameter 2 μm, particle diameter 5 μm or more about 5 wt %) was fractionated by sedimentation velocity differences in methanol (purity 99.8%) to obtain particles of relatively slow sedimentation (about 15 wt % based on the whole). 1 g of the above fractionated natural graphite was added to a mixed liquid consisting of 0.75 g of sodium nitrate, 62.1 g of sulfuric acid and 4.5 g of potassium permanganate, and the mixture was allowed to stand at about 20° C. for 5 days with stirring mildly, to obtain a high viscosity liquid. The high viscosity liquid was added to 300 cm³ of 5 wt % sulfuric acid aqueous solution with stirring. The resultant mixture was further stirred for 2 hours, to obtain a liquid. 3 g of hydrogen peroxide (30 wt % aqueous solution) was added to the above liquid and the mixture was stirred for 2 hours.

The resultant liquid was purified by centrifugation using a mixed aqueous solution of 3 wt % sulfuric acid/0.5 wt % hydrogen peroxide and centrifugation using water, to obtain an aqueous dispersion of thin film particles (concentration 0.85 wt %).

From an OM observation of a diluted solution, it was found that the average thickness of the thin film particles was less than 4 nm.

(Production of Oxidized Form Single-Layer Thin Film Particles)

Part of the before-obtained aqueous dispersion of the thin film particles having an average planar-direction size of about 20 μm and an average thickness of less than 4 nm (concentration 0.45 wt %) was subjected to centrifugation (7,000 rpm, 30 minutes). A supernatant liquid was removed and a small amount of a liquid portion (portion containing a component having a relatively large planar-direction size and a relatively small thickness) having a little high viscosity in an upper portion was taken out from the remaining dispersion. The above liquid portion was placed in a glass bottle and diluted with water by about 100 times. The glass bottle was placed on a hot plate at 150° C. and the liquid in the bottle was heated (boiled) for about 20 minutes.

The thus-obtained liquid was diluted with methanol by about 10 times. The diluted liquid was laid on a copper mesh covered by carbon microgrid and then dried. It was observed with OM in advance to confirm a domain of many overlaps of the thin film particles laid on the microgrid and a domain of a few overlaps of the thin film particles. Then, the thin film particles were observed through a transmission electron microscope.

In a low magnification observation, indistinct wrinkles (a structure in which the thin film particles stood up perpendicularly to the planar direction and then returned) were found in both the domains. When an attempt was made to observe the wrinkles in the domain of a few overlaps at a high magnification, the observation was impossible, probably because the wrinkles disappeared due to thermal influence of a strong electron beam. On the other hand, the wrinkles in the domain of many overlaps could be observed, although it was indistinct, probably because particles having wrinkles were reinforced with other particles having no wrinkles.

Particularly from an especially narrow portion of a wrinkle having a narrow width, it was found that the thickness of the thin film particles was about less than 1 nm. This thickness was near to the thickness of a fundamental layer, so that it was estimated that the thin film particles had a single-layer structure.

(Production of Oxidized Form Thin Film Particles Having a Planar Direction Size of Approximately 1 mm)

20 particles (pieces) of natural graphite having a large particle diameter (supplied by SEC Corporation, purification product, scale form, diameter about 1.4 to 2.0 mm, a thickness 0.1 mm or less) were added to a mixed liquid containing 0.34 g of sodium nitrate, 27.66 g of sulfuric acid and 2.00 g of potassium permanganate, and the mixture was allowed to stand without stirring.

Forty days later, an obtained product together with the liquid was mildly moved into 500 cm³ of a mixed aqueous solution of 3 wt % sulfuric acid/1 wt % hydrogen peroxide with a spoon. The product was wholly thinly split into a lot of transparent thin film particles. About half of the obtained thin film particles had a size of about 1 mm×1 mm, and the rest of the thin film particles were smaller particles.

5 sheets of the thin film particles having a size of about 1 mm×1 mm together with a slight amount of the liquid were taken out from the above liquid with a spoon. These particles together with the liquid were allowed to stand for about 30 minutes or more, then, the liquid was washed away, a new mixed aqueous solution was added, and these procedures were repeated 10 times, to remove manganese ions and the like. Then, similar procedures were repeated 10 times using water in place of the mixed aqueous solution, to remove the sulfuric acid and the like. During these purification procedures, the thin film particles were further split, so that the number of the particles was increased by about 5 times.

One sheet of the obtained thin film particle was taken out together with a small amount of the liquid with a spoon and then placed on a glass plate, and the liquid was dried. According to an OM observation, it was found that the particle was colored by light interference. The color had changed in each part of the particle. However, the color change (from purple to red) was only one period. Further, since the outer regions of the particle were especially thin, no coloring was found in these regions (corresponding to, what is called, a black film). Accordingly, it was estimated that the thickness of the particle was within one time the wavelength of light (approximately 700 nm in the case of a red color). From this estimation and a presumption that the refractive index of the particle was 1.5 or higher, the thickness of the particle was estimated to be about 500 nm or less in the thickest portion.

(Production of Oxidized Form Thin Film Particles Having a Planar-Direction Size of Approximately 3 mm)

Highly oriented pyrolytic graphite (supplied by Advanced Ceramics Corporation, STM-1, purity 99.99 wt % or higher, produced by heating at about 3,000° C., one piece of graphite having a thickness of 100 μm, which was obtained by cleaving graphite having a thickness of a planar direction size of 12 mm×12 mm and a thickness of 2 mm, was used) was added to a mixed liquid containing 0.34 g of sodium nitrate, 27.66 g of sulfuric acid and 2.00 g of potassium permanganate and the mixture was allowed to stand at about 10 to 20° C. without stirring. During the standing, a reaction advanced so that the graphite was split into a plurality of pieces both in the thickness direction and in the planar direction, and the pieces were swelled.

Forty days later, obtained products together with the liquid were mildly moved into 500 cm³ of a mixed aqueous solution of 3 wt % sulfuric acid/1 wt % hydrogen peroxide with a spoon. Of the products being a plurality of thinly split sheets, only two sheets were not split in their central portions and still had a black color. The others were transparent thin film particles. Most of the thin film particles had a size of 5 mm×5 mm or less, the average size of the particles was approximately 3 mm×3 mm. Further, most of the particles had a contour having an irregular form and a straight-line portion derived from the contour of the raw graphite was partially included.

After the liquid containing the thin film particles was allowed to stand for about 30 minutes, the liquid was removed and a new mixed aqueous solution was added thereto. These procedures were repeated 10 times, to remove manganese ions and the like. Then, similar procedures were repeated with water in place of the above aqueous solution 10 times, to remove the sulfuric acid and the like. During these purification procedures, the thin film particles were further split so that the number of the particles was increased by about 10 times.

One sheet of the obtained thin film particle was taken out together with a small amount of the liquid with a spoon and then placed on a glass plate. The liquid was dried and the thin film particle was observed through OM. It was estimated that the thickness of the particle in the thickest portion was about 500 nm or less.

(Production of Oxidized Form Lamination Layer Aggregate)

Methanol (relative dielectric constant at 25° C., 32.7) was added to the before-obtained aqueous dispersion (concentration 0.45 wt %) of the thin film particles having an average planar-direction size of about 20 μm and an average thickness of less than 4 nm to obtain a 0.1 wt % dispersion. Methanol was further added to this dispersion to obtain a 0.01 wt % methanol dispersion containing a slight amount of water. This dispersion was placed in a glass container having a plane bottom such that the depth of the dispersion was about 2 cm. The glass container was covered with a lid and the dispersion in the glass container was allowed to stand at about 20° C. During the standing, the thin film particles precipitated. About 90 days later, there were obtained large-scale particles having a planar-direction size of 500 μm or more, which particles floated in the dispersion when the dispersion was mildly shaken, and could be distinguished by the unaided eye.

One sheet of the above large-scale particle was taken out together with a small amount of the liquid with a spoon and moved onto a glass plate, and the liquid was dried. From an OM observation, it was confirmed that the large-scale particle was a lamination layer aggregate composed of a plurality of small thin film particles which were mutually laminated and assembled.

Further, the lamination layer aggregate was observed after it was heated at 500° C. (details on the heating will be described later). An increase in the reflective index by reduction made the contour of each thin film particle, which constituted the lamination layer aggregate, clear. Further, it was found that the number of the laminated thin film particles inside the lamination layer aggregate was about 10 or less on average, although it differed in places. From this, it was estimated that the thickness of the lamination layer aggregate was several tens nm. Further, a large bending portion, caused when the lamination layer aggregate was placed on the glass plate, existed in a portion of the inside of the lamination layer aggregate. In the above large bending portion, the respective thin film particles, which constituted the lamination layer aggregate, were also bent. In addition, it was supposed that each fundamental layer being a large-scale planar molecule was also bent.

(Reduction by Heating and Changes of Particles)

The before-prepared aqueous dispersion of the oxidized form thin film particles having an average planar-direction size of about 20 μm and an average thickness of less than 4 nm was placed on a borosilicate glass substrate such that the dispersion spread to about 1 cm×1 cm and that the thickness after drying was about 30 μm. A dust protector was provided and then the dispersion on the glass substrate was allowed to stand at about 20° C. at a relative humidity of about 40%, to dry it. Then, the thin film particles on the glass substrate were heated in vacuum with increasing a temperature gradually (further, concerning heating at a high temperature of 1,200° C., the thin film particles were heated in argon after peeling off from the glass plate), and interlayer distance changes were checked by an X-ray diffraction measurement (measured in the air at about 20° C.).

As the heating temperature increased, peaks which gave interlayer distances changed from the peak of graphite oxide alone (corresponding to a layer structure containing oxygen, interlayer distance at 20° C. 0.83 nm), through coexistence of the peak of graphite oxide and a peak toward a peak similar to that of graphite (corresponding to coexistence of a layer structure portion containing oxygen and a layer structure portion not containing oxygen very much, interlayer distances at 150° C. 0.55 nm and 0.38 nm), to the peak similar to that of graphite alone (corresponding to a layer structure containing almost no oxygen or containing no oxygen, the broadening of the peak was larger than that of graphite, interlayer distance at 300° C. 0.37 nm, interlayer distance at 1,200° C. 0.34 nm).

The color tone and electric resistance (a simplified measurement was carried out at a distance between electrodes of approximately 1 mm using a general circuit tester, the electric resistance of a lower-oriented graphite sheet having a thickness of 0.5 mm was 1.5Ω according to the same method) were respectively blackish brown and 32 MΩ or more (beyond a measurement range) at 20° C., deep blackish brown and 20 MΩ at 100° C., dark silver and 10 kΩ at 150° C., silver and 300Ω at 200° C., and bright silver and 5Ω at 1,200° C. Further, according to a thermogravimetric analysis, weight losses at particularly about 150° C.˜210° C. were remarkable.

One sheet of the before-obtained oxidized form thin film particle having a size of about 3 mm×3 mm and a thickness of less than 500 nm was laid on a borosilicate glass substrate by using a spoon and the particle was dried at room temperature. Then, the particle was temperature-increased from about 2° C. to 300° C. in the air over about 20 hours, then temperature-increased from 300° C. to 500° C. over 1 hour, and allowed to stand at 500° C. for 1 hour. Then, the particle was temperature-decreased to about 20° C. The particle had been converted to a reduced form particle having a silver color.

One sheet of the before-prepared oxidized form lamination layer aggregate on the glass plate was temperature-increased from about 20° C. to 300° C. in the air over about 5 hours, then temperature-increased from 300° C. to 500° C. over 1 hour, and allowed to stand at 500° C. for 1 hour. Then, the lamination layer aggregate was temperature-decreased to about 20° C. The lamination layer aggregate had been converted to a reduced form lamination layer aggregate having a semi-translucent silver color.

(Exchange of Dispersion Medium)

The before-obtained aqueous solution of the oxidized form thin film particles having an average planar-direction size of about 20 μm and an average thickness of less than 4 nm was placed in a centrifugal bottle. Acetone (relative dielectric constant at 25° C. 20.7, purity 99.5%, about two times to four times the aqueous dispersion, the magnification increased as procedures advanced) was added to the above aqueous solution, and redispersing, centrifugation (7,000 rpm, 30 minutes) and removal of a supernatant liquid were repeated three times in total. An obtained precipitation had a concentration of about 1.7 wt % and it was a lump having no flowability.

Further, 2-butanone (relative dielectric constant at 20° C. 18.5, purity 99%, about four times the acetone dispersion) was added to the above lump in the centrifugal bottle, and redispersing, centrifugation (7,000 rpm, 30 minutes) and removal of a supernatant liquid were repeated three times in total. An obtained precipitation had a concentration of about 2.0 wt % and it was a lump having no flowability.

As described above, a disperse system of the oxidized form thin film particles could be prepared by using a liquid other than water. However, inter-particle repulsion decreased in accordance with a decrease in dielectric constant so that a precipitation having a higher concentration was easily produced. Further, since the thin film particles had a high anisotropy of shape, a surrounding dispersion medium was held even at a low concentration of several % so that the flowability of the dispersions was extremely decreased.

One sheet of the before-obtained oxidized form thin film particle having a size of about 3 mm×3 mm and a thickness of less than 500 nm was added to methanol with a spoon, to exchange dispersion mediums.

(Increase in the Affinity of Substrate)

Various substrates were increased in affinity (hydrophilization treatment), then oxidized form thin film particles were adhered to the substrates, and the particles were reduced by heating. In this case, the degree of hydrophilization was evaluated by a contact angle to water. The contact angle was determined by dropping water on each substrate. It was calculated using the volume of the dropped water (e.g., 3 mm³) and the diameter of a droplet contact face measured on the substrate (when the contact angle was less than 90 degree) or the diameter of the droplet (when the contact angle was 90 degree or more) on the basis of the assumption that the shape of the droplet was a part of a sphere.

A diamond substrate (supplied by Sumitomo Electric Industries, Ltd., polycrystal, a product obtained by allowing diamond crystals to grow up on a silicon substrate and polishing its surface, diamond layer thickness 25 μm) was washed with methanol (immersed in the methanol and subjected to ultrasonication for 3 minutes) and then washed with water (immersed in the water and subjected to ultrasonication for 3 minutes). Then, the substrate was dried (the water was blown off with compressed air). Then, the substrate was further heated at 500° C. in the air for 1 hour. After the substrate was cooled, it was immersed in water and then dried (the same). The contact angle was step by step changed as follows. The contact angle was 97 degree before the treatments, it was 52 degree after the wash with water and the drying, and it was 8 degree after the heating and the immersion and the drying.

A silicon carbide substrate (supplied by Hitachi Chemical Co., Ltd., polycrystal, thickness 5 mm) was treated similarly to the diamond substrate. The changes of the contact angle were similarly checked, and the contact angles were 87 degree, 72 degree, and 17 degree respectively.

A silicon substrate (silicon wafer, single crystal, thickness 0.4 mm) was treated similarly to the diamond substrate. The changes of the contact angle were similarly checked and the contact angles were 51 degree, 50 degree and 29 degree respectively. In addition, the silicon wafer was immersed in a 10 wt % sodium hydroxide aqueous solution for 1 minute and then dried (the same). The contact angle was 18 degree.

A sapphire substrate (supplied by Kyocera Corporation, SA100, single crystal, one-side polished piece, thickness 0.43 mm) was treated similarly to the diamond substrate. The changes of the contact angle were similarly checked and the contact angles were 33 degree, 28 degree and 5 degree respectively.

A silica glass substrate (amorphous, polished product, thickness 2 mm) was treated similarly to the diamond substrate. The changes of the contact angle were similarly checked and the contact angles were 46 degree, 43 degree and 6 degree respectively.

A non-alkaline glass substrate (supplied by Nippon Electric Glass Co., Ltd., OA-10, main components were silica and alumina, amorphous, polished product, thickness 0.7 mm) was treated similarly to the diamond substrate. The changes of the contact angle were similarly checked and the contact angles were 34 degree, 32 degree and 14 degree respectively.

The contact angle of a borosilicate glass substrate without any treatment (slide glass, amorphous, polished and washed product, thickness 1.2 mm) was 4 degree.

A different diamond substrate was subjected to sputtering (Ar ion, applied voltage 10 kV, electric current density 200 to 300 μA/cm², 6 hours). Then, it was heated at 500° C. for 1 hour. Then, it was cooled. The cooled substrate was immersed in water and then dried (the same). The contact angle after the sputtering was 47 degree. It was changed to 6 degree after the heating and the immersion and the drying.

(Observation Through Atomic Force Microscope)

The before-obtained oxidized form thin film particles having an average planar-direction size of about 20 μm and an average thickness of less than 4 nm in the form of a 0.01 wt % methanol dispersion were placed on a silicon substrate (no hydrophilization in order to avoid a flatness decrease as far as possible). The particles were dried and then the particles were observed through an atomic force microscope. Moreover, the particles were reduced by heating at 300° C. for 10 minutes. Then, the particles were cooled to a room temperature and the particles were observed again.

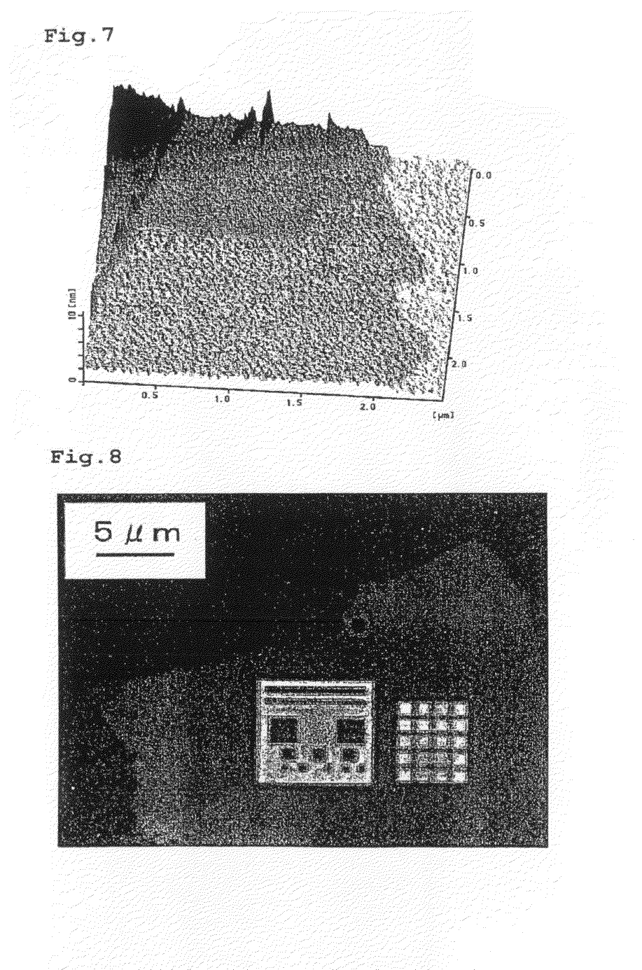

A lot of the particles had a plurality of extremely mild wrinkles inside the particles. In some portions, there were found differences in level which were thought to be a structure formed by folding the thin film particles (FIG. 7). These bending portions of the thin film particles were not thick and these portions were intensely bent. It was estimated that each fundamental layer being a large-scale molecule was intensely bent in these portions. Further, in other portions, there were found stages (steps) having a constant width in level which were thought to be a two-stage-bending structure where the thin film particles bent once and then bent to the opposite side again.

Moreover, a change in thickness before and after the heating was checked in a particularly thin portion. A portion having a thickness of 2.1 nm before the heating was changed to a thickness of 1.1 nm after the heating. The above ratio was near to a ratio of lattice spacing change (0.83 nm and 0.37 nm) according to the before-mentioned X-ray diffraction.

(Adhesion of Thin Film Particles on a Substrate)

Two kinds of dispersions containing a lot of oxidized form thin film particles (the two kinds of dispersions respectively including particles having an average planar direction size of less than about 2 μm (concentration 0.85 wt %) and particles having an average planar direction size of about 20 μm (concentration 0.45 wt %), each dispersion was applied such that the spread, as a whole, became about 0.5 cm² and the average thickness after drying became about 2 μm), an oxidized form thin film particle having a planar-direction size of about 2 mm×2 mm and a thickness of less than 500 nm (one sheet, moved together with a small amount of a liquid with a spoon), and an oxidized form lamination layer aggregate having a planar-direction size of about 500 μm (one sheet, the same), four kinds in total, were respectively placed on each of the above hydrophilization-treated various substrates (each substrate having the smallest contact angle). The substrates were respectively allowed to stand at about 20° C. for 15 hours and then dried. The respective substrates were mildly temperature-increased at a rate of about 50° C. per 1 hour and the thin film particle(s) and the lamination layer aggregate were reduced by heating at a maximum temperature of 500° C. for 1 hour. In all cases, the thin film particle(s) or the lamination layer aggregate were/was finely placed on the substrate.

(Pattern Formation by Irradiation of Ion Beam)

Part of the inside of thin film particle(s) was removed by irradiation of a focussed ion beam, thereby processing (pattern formation) the inside of the thin film particle(s) in a selected position.

About five droplets of a 0.01 wt % methanol dispersion of oxidized form thin film particles having a planar-direction size of about 20 μm were placed on a borosilicate glass substrate and then dried. Then, the thin film particles were reduced by heating at 300° C. For preventing electrification of a sample at the time of processing, three sides of a processing object portion having a size of about 3 mm×3 mm were coated with an electrically conductive paste. This sample was observed with an optical microscope in advance and a plurality of thin film particles having little contact with other particles and having little macroscopically wrinkles were selected. The insides of these particles were finely processed with a focussed ion beam apparatus (supplied by Hitachi, Ltd., FB-2000A, gallium as an ion source, the maximum scanning region by one irradiation was 60×60 μm, minimum resolving power 10 nm). The shapes by processing were a network lattice (a plurality of squares were irradiated by ions to leave a plurality of boundaries of the squares), a plurality of linear shapes (long and slender rectangles, the minimum width was about 100 nm) and squares (these were left and circumferences thereof were ion-irradiated, about three kinds of sizes each) on the supposition of a conducting lead or a quantum structure.

A current quantity and an irradiation time were changed at an acceleration voltage of 30 kV and several particles were individually irradiated. The degree of processing was checked using an image of a secondary electron observed in the focussed ion beam apparatus at the time of the irradiation and an image observed with an outer optical microscope (FIG. 8). Adequate processing was possible with an electrical charge quantity of about 5 to 60 pC/μm² (an ion amount of about 5 to 60×10⁻¹⁷ mol/μm² on a supposition of a monovalent ion). Further, when an irradiation dose was small to the thickness of the particles, the processing was insufficient. When it was large, peelings occurred.

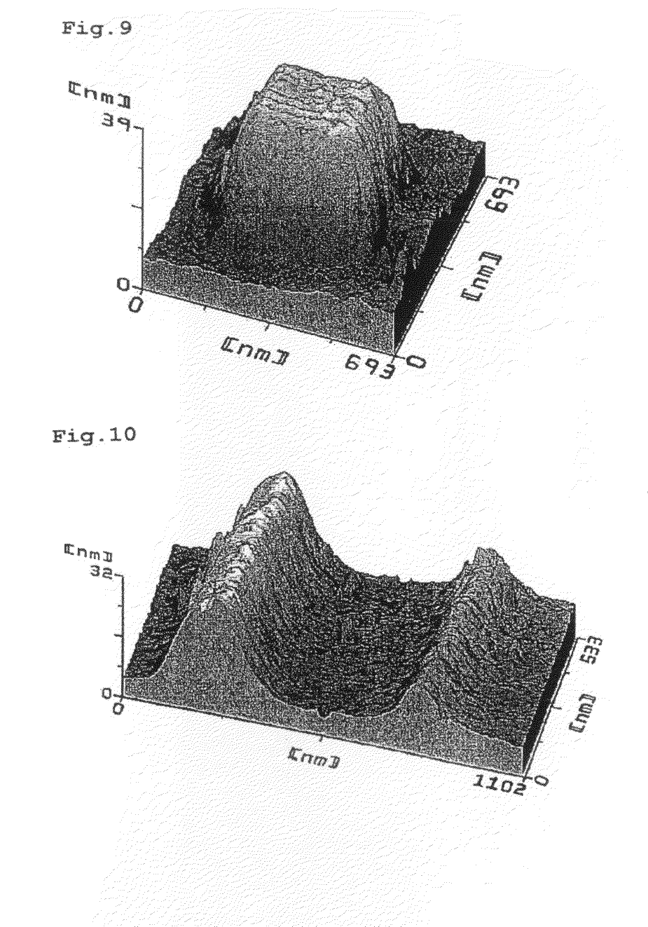

Further, the obtained processed article was observed with an atomic force microscope, to confirm that the thickness of each thin film particle was about 10 nm, that the thin film particles were processed in a desired shape in the height direction (the thickness direction of the particle), and that a thin wire having a line width of about 100 nm was processed (FIG. 9, FIG. 10). In this case, it was supposed that the inside of each fundamental layer being a large-scale molecule was also processed.

As described above, the inside of the isolated thin film particle laid on the substrate could be concretely pattern-formed. Such shapes can be respectively applied to a fine wiring or device by feeding electricity and to a recording material (recording medium) by, for example, treating the presence or absence of thin film particles in processed portions as information.

(Pattern Formation by Screen Printing)

Pattern formation was carried out by mounting a lot of thin film particles on a substrate in a selected position.

By printing using a screen mask, there was produced wiring (two lines having a 1 mm with a gap having a width of 1 mm, thickness about 20 μm) for an outside connection on a non-alkaline glass substrate (OA-10) with a gold paste (supplied by Heraeus K.K, C4350, gold ratio 90 wt %, the paste was fixed by heating at 600° C., the heating carried out hydrophilization of the substrate at the same time).

In addition, by printing using a different screen mask, a pattern of a square shape having a size of 3 mm×3 mm and a thickness, after drying, of about 700 nm was formed in a position where the pattern was partially disposed on each of the two wiring lines, by using as an ink an aqueous dispersion (concentration 1.6 wt %, concentrated by centrifugation) of the before-obtained oxidized form thin film particles having an average planar-direction size of about 20 μm and an average thickness of less than 4 nm.

(Measurement of Electric Conductivity)

While the structure matter obtained by the above pattern formation by screen printing was reduced by heating, changes of electric conductivity (accurately, relative dielectric constant) were measured (the same sample was step by step heated and measured, measurements in the air at room temperature). Here, in the calculation of the electric conductivity, it was assumed that the heating caused no changes in a space between the gold wiring lines and in the planar-direction dimension of the pattern-formed thin film particles. Further, the thickness was measured at only after 200° C.-heating through an atomic force microscope. The thickness at other temperatures was calculated from interlayer distance changes obtained by an X-ray diffraction method. The electric conductivity was 0.0027 S/m or less before heating (resistance value beyond a measurement range), 0.0029 S/m or less (the same) after heating at 100° C. for 30 minutes, 120 S/m after heating at 200° C. for 210 minutes, 220 S/m after heating in vacuum at 300° C. for 90 minutes, 780 S/m after heating in vacuum at 400° C. for 90 minutes, and 1,600 S/m after heating in vacuum at 500° C. for 90 minutes.

By printing using a different screen mask, there was produced the first wiring (two parallel zonal lines having a 1 mm with a gap having a width of 1 mm, thickness about 0.3 μm) for an outside connection an a sapphire substrate (SA100) with a gold paste (supplied by Heraeus K.K, PR20003, gold ratio 20 wt %, the paste was fixed by heating at 850° C., the heating carried out hydrophilization of the substrate at the same time). In addition, the second wiring (thickness about 20 μm) was formed with a gold paste (supplied by Heraeus K.K, C5755A, gold ratio 86 wt %, the paste was fixed by heating at 850° C.) such that the second wiring and the first wiring partially overlapped each other as if the first wiring was extended. In addition, one sheet of the above-mentioned oxidized form thin film particle having a size of 3 mm×3 mm and a thickness of less than 500 nm together with a small amount of a liquid was laid with a spoon in a position where two portions of the particle were respectively disposed on the two lines of the first wiring. Then, the particle was dried, to obtain a structure matter. While the structure matter was reduced by heating, electric conductivity changes were measured. The electric conductivity was 0.0020 S/m or less before heating (resistance value beyond a measurement range), 0.0021 S/m or less after heating at 100° C. for 30 minutes (the same), 2.2 S/m after heating at 200° C. for 210 minutes, 5.2 S/m after heating in vacuum at 300° C. for 90 minutes, 37 S/m after heating in vacuum at 400° C. for 90 minutes, and 96 S/m after heating in vacuum at 500° C. for 90 minutes. Further, it was confirmed that the contact portions with the gold wiring lines were ohmic contacts.

### Example 2

The aqueous dispersion, having a concentration of 0.45 wt %, of the oxidized form thin film particles, which had an oxygen content of about 42 wt % and a hydrogen content of about 2 wt % according to the elemental analysis results of the particles after vacuum-drying at 40° C. and had a planar-direction size of about 20 μm, obtained in Example 1, was used as a dispersion A. The following experiments were carried out using the dispersion A.

Two gold wiring lines were formed on a silica glass substrate at a space of 2 mm. A thin film layer formed of the thin film particles was formed such that the thin film layer straddled the two wiring lines. The film formation was carried out by dropping the dispersion A between the wiring lines with a pipet and drying the dispersion medium at 80° C. for 15 minutes. The thickness of the film after the drying was about 1 μm. The thus-obtained thin film layer was irradiated with light of an ultrahigh pressure mercury lamp (supplied by Ushio Inc., USH-500D, 500 W) from a distance of 20 cm. After irradiation for 20 minutes, the thin film layer was measured for resistance. From the measured resistance value, the resistivity of the thin film particles was calculated and it was 900 Ω·cm. Further, the film layer was irradiated for 20 minutes and the resistivity was 50 Ω·cm.

The state of carbons was checked by XPS (X-ray photoelectron spectroscopy). Although two peaks were found at 284.5 eV (derived from C—C and C═C bonds) and 286.5 eV (derived from C—O bonds) before the light irradiation, the peak of 286.5 eV largely decreased after the light irradiation. This showed that the ratio of carbon bonded to oxygen decreased and the ratio of carbon bonded to carbon increased. In addition, it was confirmed from IR (infrared spectroscopy) analysis that hydroxyl groups were decreased by the light irradiation.

### Example 3

Similarly to Example 2, the dispersion A was dropped between two gold wiring lines on a silica glass substrate, the dispersion was dried at 80° C. for 15 minutes to form an about 1 μm-thick thin film layer formed of the thin film particles. The thus-produced thin film layer was irradiated with light of a xenon lamp (300 W) from a distance of 15 cm. After irradiation for 40 minutes, the thin film layer was measured for resistance. The resistivity of the thin film particles was calculated from the measured resistance value, to find it was 1,500 Ω·cm. Further, the thin film layer was irradiated for 80 minutes and the resistivity became 50 ∩·cm.

### Example 4

There was produced a metal mask in which two apertures having a width of 1 mm×a length of 5 mm were formed at an interval of 2 mm in a central portion, for the purpose of producing, as a reduction line pattern, two lines having a line width of 1 mm and a length of 5 mm at an interval of 2 mm in a thin film layer formed of thin film particles.

The dispersion A was dropped in a domain of approximately 20 mm×20 mm in a central portion of a silica glass substrate, and it was dried at 80° C. for 15 minutes, to form a thin film layer formed of the thin film particles. The thickness of the film after the drying was about 0.1 μm. The metal mask was placed such that the above apertures were disposed on the thin film layer. The thin film layer was irradiated with light of the same ultrahigh pressure mercury lamp as that used in Example 2 from a distance of 20 cm for 40 minutes. In the thin film layer after the light irradiation, as a result, only portions where the light was transmitted through the apertures of the mask, i.e., two line portions having a size of 1 mm×5 mm, were changed from brown to black, while the other portions still had the same brown color as that before the irradiation. A metal mask pattern was transferred.

### Example 5

3 g of the dispersion A was added to 147 g of water (relative dielectric constant 70 to 80), and the mixture was irradiated with light of the same ultrahigh pressure mercury lamp as that used in Example 2 from a distance of 20 cm for 60 minutes while stirring with a stirrer. The dispersion A was light brown before the light irradiation. After the light irradiation, the color was changed to black because of reduction. Further, the high disperse state of the thin film particles was maintained.

The dispersion A after the light irradiation was dropped between two gold wiring lines on a silica glass substrate similarly to Example 2, and the dispersion A was dried at 80° C. for 15 minutes, to form an about 1 μm-thick thin film layer formed of the thin film particles. Then, the thin film layer was measured for resistance, and the resistivity of the thin film particles was calculated from the measured resistance value, to find it was 2,000 Ω·cm.

### Example 6

3 g of the dispersion A was added to a mixed liquid containing 72 g of water (relative dielectric constant 70˜80) and 75 g of 1-butanol (relative dielectric constant 17.1), and the mixture was irradiated with light similarly to Example 5. As a result, although the dispersion A had a light brown color before the light irradiation, the color was changed to black after the light irradiation because of reduction. Further, the high disperse state of the thin film particles was maintained. The resistivity of the thin film particles after the light irradiation was calculated similarly to Example 5 to find it was 3,000 Ω·cm.

### Example 7

3 g of the dispersion A was added to 147 g of ethanol (relative dielectric constant 23.8), and the resultant mixture was irradiated with light similarly to Example 5. As a result, although the dispersion A had a light brown color before the light irradiation, the color was changed to black after the light irradiation because of reduction. Further, the high disperse state of the thin film particles was maintained. The resistivity of the thin film particles after the light irradiation was calculated similarly to Example 5 to find it was 2,000 Ω·cm.

### Example 8

3 g of the dispersion A was added to a mixed liquid containing 50 g of water (relative dielectric constant 70˜80) and 50 g of methyl ethyl ketone (relative dielectric constant 18.51), and the resultant mixture was irradiated with light similarly to Example 5. As a result, although the dispersion A had a light brown color before the light irradiation, the color was changed to black after the light irradiation because of reduction. Further, the high disperse state of the thin film particles was maintained. The resistivity of the thin film particles after the light irradiation was calculated similarly to Example 5 to find it was 4,000 Ω·cm.

### Example 9

0.5 g of the dispersion A was added to 24.5 g of 1,4-butanediol (relative dielectric constant 31.1), and the mixture was irradiated with light similarly to Example 5. As a result, although the dispersion A had a light brown color before the light irradiation, the color was changed to black after the light irradiation because of reduction. Further, the high disperse state of the thin film particles was maintained. The resistivity of the thin film particles after the light irradiation was calculated similarly to Example 5 to find it was 3,000 Ω·cm.

### Example 10

First, a dispersion was taken from the same light-irradiated sample (dispersion of thin film particles using ethanol as a dispersion medium) as that obtained in Example 7 with a pippet. Then, the dispersion taken was dropped on a water surface. As a result, a homogeneous film of the thin film particles was formed on the water surface. The film formed on the water surface was not a monomolecular film so that it could not be called a LB (Langmuir-Blodgett) film. However, the formed film was a thin and homogeneous film like a LB film. This was because the dispersion medium in the dispersion was dispersible in water but the reduced thin film particles became unfamiliar with water and floated on the water surface.

### Example 11

The same film of the thin film particles as that formed on the water surface in Example 10 was transferred to a substrate by the same method as that used for a LB film. In the method, after the film was formed on water surface, a substrate prepared separately was vertically immersed into water and then the substrate was slowly raised up. The thin film layer formed on the substrate was extremely homogeneous.

### Example 12

The aqueous dispersion, having a concentration of 0.45 wt %, of the oxidized form thin film particles, having an oxygen content of about 42 wt % and a hydrogen content of about 2 wt % according to the elemental analysis results of the particles after vacuum-drying at 40° C. and having a planar direction size of about 20 μm, obtained in Example 1, was used as a dispersion A. The following experiments were carried out using the dispersion A.

(Production of a Device for Measuring Mobility)

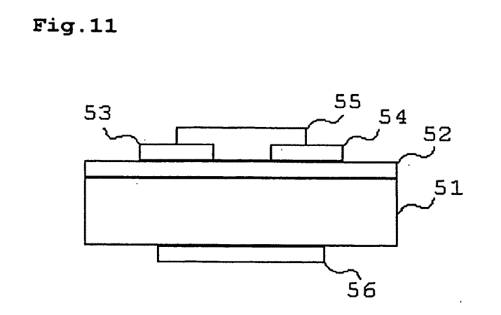

A device for measuring mobility will be explained in accordance with FIG. 11. A thermally oxidized film 52 having a thickness of 250 nm was formed on a highly doped N type silicon wafer 51. The N type silicon wafer 51 works as a substrate and also works as a gate electrode. Cr and Au were vapor-deposited in vacuum on a back surface of the substrate for an ohmic contact, to form an electrode 56. Then, a source electrode 53 and a drain electrode 54 were formed on the thermally oxidized layer 52. Cr and Au were vapor-deposited in vacuum on the source electrode 53 and the drain electrode 54 through a shadow mask. A channel width was 1,000 μm and a channel length was 200 μm. Finally, a channel layer 55 was formed such that it straddled the source electrode 53 and the drain electrode 54. As the channel layer 55, there was used a layer obtained by dropping 1 μl of a 10-times diluted liquid of the above dispersion A and then removing the dispersion medium by drying.

(Mobility Measurement Method)

When various gate voltages were applied in a state where a constant voltage (typically 10 V) was applied between the source electrode 53 and the drain electrode 54, electric currents flowing between the source electrode 53 and the drain electrode 54 were monitored. Measurements were carried out in vacuum.

(Mobility Calculation Method)

The present invention's mobility was calculated by the formula (I) with a fixed drain voltage.

I_{DS}=(W/L)μCᵢ[(V_{G}−Vₒ)V_{D}−V_{D}²/2]+Iₒ (1)

wherein I_{DS} is a source-drain current, W and L are a channel width and a channel length respectively, μ is a field effect mobility, Cᵢ is a capacity per unit area of an insulation layer, V_{G}, V_{D} and Vₒ are a gate voltage, a drain voltage and a threshold voltage respectively, and Iₒ is an ohmic current flowing through a semiconductor film.

The calculations were carried out on the assumption that Iₒ was not influenced by a gate bias. Further, although it is a general phenomenon in an organic semiconductor, the source-drain current, which increased immediately after the gate voltage was applied, gradually decreased in the present invention. Therefore, an electric current value immediately after the application of the gate voltage was measured.

(Mobility Measurement)

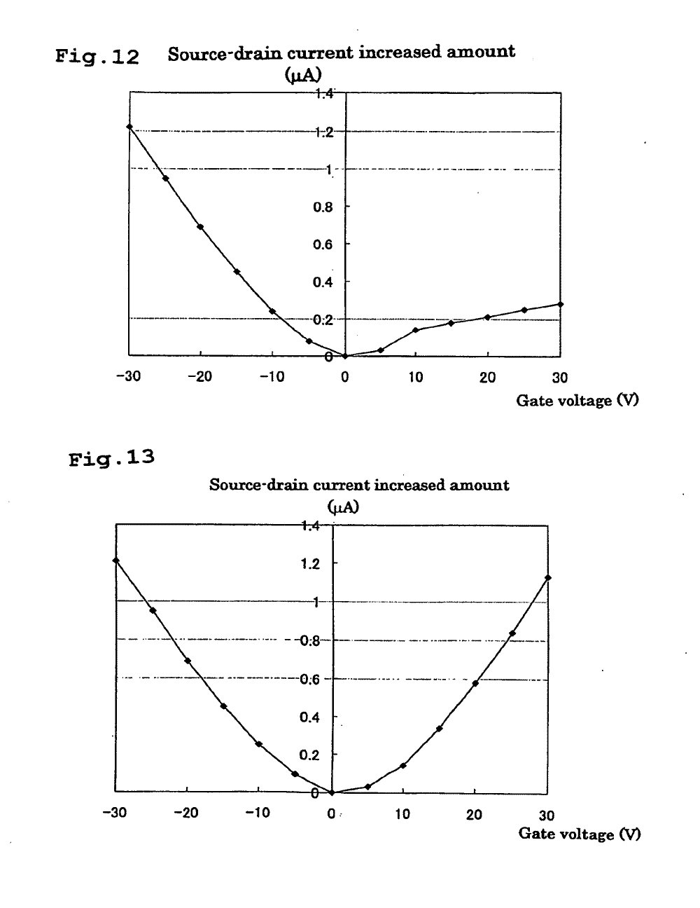

The device for measuring mobility, prepared as above, was subjected to heating-reduction treatments under three conditions of (1) 200° C., 30 minutes, (2) 250° C., 60 minutes, and (3) 300° C., 240 minutes. Samples prepared as above worked as ambipolar. In short, the gate voltage was changed while fixing the source-drain voltage. In this case, the source-drain current increased in accordance with an increase in the absolute value of the gate voltage in both a case in which the gate voltage was positive (N type) and a case in which it was negative (P type). FIG. 12 shows a current-voltage character of a sample reduced by heating at 300° C. for 240 minutes. Measurements were carried out while shielding light. When light was not shielded, an electric-current increased-amount increased in the case of N type. FIG. 13 shows a current-voltage character shown when light was not shielded.

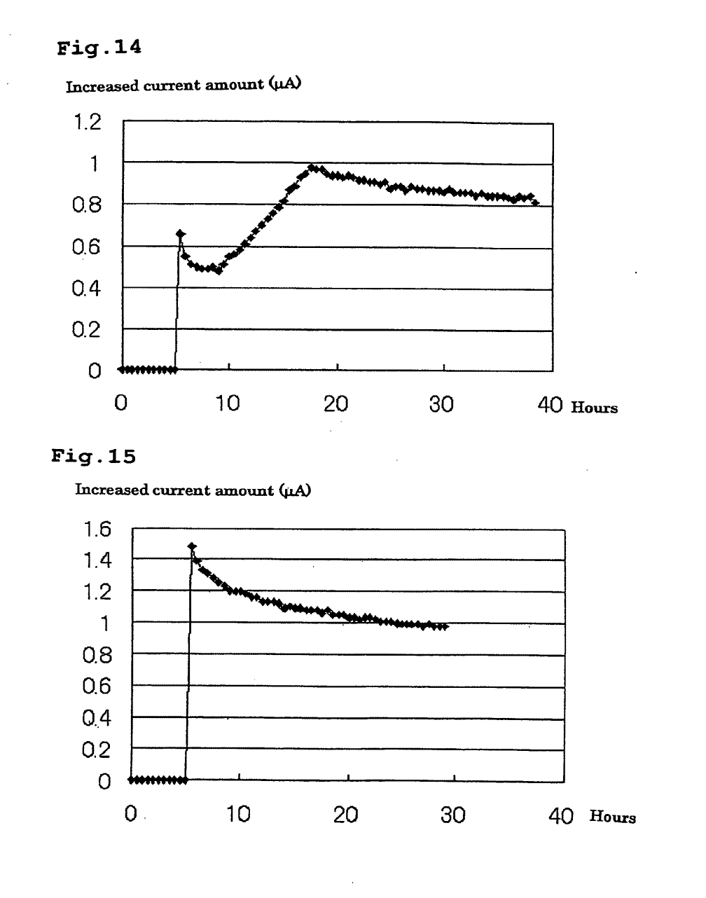

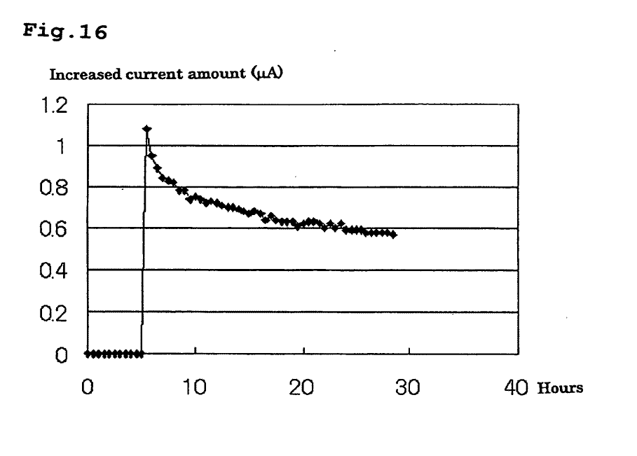

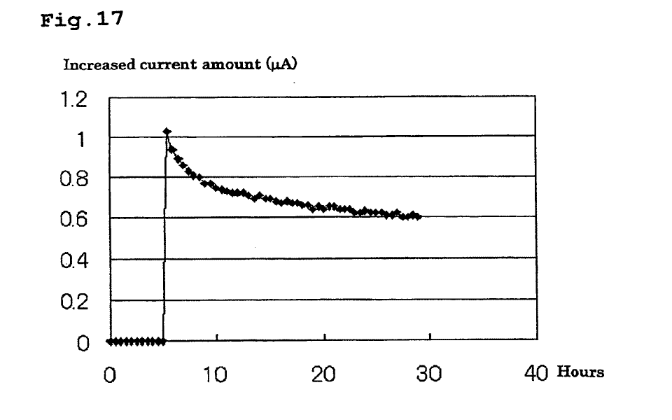

In relate to the above phenomenon, changes in a source-drain current increased amount were checked from immediately after applying a gate voltage. FIG. 14 shows changes in a source-drain current increased-amount from immediately after applying a positive gate voltage (N type) in a state of shielding light. FIG. 15 shows changes in a source-drain current increased-amount from immediately after applying a positive gate voltage (N type) without shielding light. FIG. 16 shows changes in a source-drain current increased-amount from immediately after applying a negative gate voltage (P type) in a state of shielding light. FIG. 17 shows changes in a source-drain current increased-amount from immediately after applying a negative gate voltage (P type) without shielding light. Further, the gate voltage was applied at the time of 5 s in each of FIGS. 14 to 17.

In FIG. 14, when the positive gate voltage (N type) was applied in a state of shielding light, the electric current increased in two stages, that is, the electric current increased immediately after the application of the gate voltage and then decreased once, and then the electric current increased again and then decreased. In contrast, when the positive gate voltage (N type) was applied without shielding light (FIG. 15), the electric current increased immediately after the application of the gate voltage and then the electric current only decreased. When the negative gate voltage (P type) was applied, the electric current increased immediately after the application of the gate voltage and then only decreased regardless of shielding of light (FIGS. 16 and 17).

The above phenomenons teach that, in the case of N type, the source-drain current increased amounts measured immediately after the applying of the gate voltages largely varied depending upon whether the light was shielded or not. Table 1 shows mobility in each treatment condition in the light-shielding cases and in the non-light-shielding cases.

TABLE 1

| | With light shielding | | Without light shielding | |
|---|---|---|---|---|
| | Mobility | Mobility | Mobility | Mobility |
| Treatment | of N type | of P type | of N type | of P type |
| conditions | (cm²V⁻¹s⁻¹) | (cm²V⁻¹s⁻¹) | (cm²V⁻¹s⁻¹) | (cm²V⁻¹s⁻¹) |
| 200° C., | 6.0 × 10⁻⁴ | 4.0 × 10⁻⁴ | 6.8 × 10⁻⁴ | 4.1 × 10⁻⁴ |
| 30 min. | | | | |
| 250° C., | 6.5 × 10⁻³ | 1.8 × 10⁻² | 2.6 × 10⁻² | 1.9 × 10⁻² |
| 60 min. | | | | |
| 300° C., | 2.2 × 10⁻² | 1.5 × 10⁻² | 7.6 × 10⁻² | 7.4 × 10⁻² |
| 240 min. | | | | |

Table 1 teaches that the mobility increased as the heating temperature increased. Further, it is found that the obtained mobility was high or 10⁻¹ to 10⁻² (cm²V⁻¹s⁻¹).

1-21. (canceled)

22. A method for reducing thin film particles which are obtained by oxidizing graphite, are dispersible in a liquid having a relative dielectric constant of 15 or higher and have a carbon skeleton,
comprising irradiating the thin film particles with light.

23. A method according to claim 22,
wherein the thin film particles have a thickness of 0.4 nm to 100 nm and a planar-direction size of 20 nm or more.

24. A method according to claim 22,
wherein the light to be irradiated has a wavelength in the range of from 100 nm to 1,100 nm.

25. A method according to claim 22,
wherein the resistivity of the thin film particles after the light irradiation is decreased to 10,000 Ω·cm or less.

26. A method according to claim 22,
wherein a dispersion of the thin film particles is irradiated with the light.

27. A method according to claim 22,
wherein a dispersion of the thin film particles is applied to a substrate to obtain a thin-film layer made of the thin film particles, and then the entire surface of the thin film layer or a desired portion of the thin film layer is irradiated with the light.

28-36. (canceled)
